(19) United States
(12) Patent Application Publication
(10) Pub. No.: US 2026/0353913 A1
(43) Pub. Date: Nov. 5, 2026

(54) ORGANIC ELECTROLUMINESCENT DEVICE

(71) Applicant: DuPont Specialty Materials Korea Ltd., Chungcheongnam-do (KR)

(72) Inventors: Hae-Yeon KIM, Gyeonggi-do (KR); Sung-Woo JANG, Gyeonggi-do (KR); Chi-Sik KIM, Gyeonggi-do (KR); Mi-Ja LEE, Gyeonggi-do (KR); Tae-Jin LEE, Gyeonggi-do (KR); Young-Kwang KIM, Gyeonggi-do (KR)

(21) Appl. No.: 19/642,991

(22) Filed: Apr. 9, 2026

(30) Foreign Application Priority Data
Apr. 22, 2025 (KR) 10-2025-0052093

(51) Int. Cl. H10K 50/12; H10K 85/60; H10K 101/00; H10K 101/10; H10K 101/40

(52) U.S. Cl. CPC H10K 50/12; H10K 85/622; H10K 85/626; H10K 85/633; H10K 85/636; H10K 85/654; H10K 85/656; H10K 85/6572; H10K 85/6574; H10K 85/658; H10K 2101/10; H10K 2101/40; H10K 2101/90

(57) ABSTRACT

The present disclosure relates to an organic electroluminescent device, and by comprising a compound according to the present disclosure, it is possible to provide an organic electroluminescent device exhibiting higher current efficiency and superior lifespan characteristics as compared with conventional organic electroluminescent devices.

### TECHNICAL FIELD

The present disclosure relates to an organic electroluminescent device.

### BACKGROUND ART

Organic electroluminescent devices (OLEDs) are self-emissive devices and have been widely used in the display and lighting industries due to advantages such as a wide color gamut, high contrast ratio, and fast response speed. In general, an OLED has a structure in which an organic thin film layer including a light-emitting layer is stacked between an anode and a cathode. When an electric current is applied, electrons and holes recombine to form excitons, and light is emitted through radiative decay of the excitons.

Recently, in order to further improve the performance of OLEDs, structures including a plurality of light-emitting layers have been actively studied. In a conventional single light-emitting layer (single EML) structure, emission of a specific color may not be efficiently achieved, or the device lifespan may be limited. Accordingly, a multilayer light-emitting structure including a plurality of light-emitting layers having different emission characteristics has been introduced. Through such a structure, luminous efficiency can be improved, color purity and color tuning characteristics can be enhanced, and the lifespan and stability of the device can be improved.

In OLEDs including such a plurality of light-emitting layers, the selection of light-emitting materials included in the respective light-emitting layers is particularly important, in view of careful consideration of charge injection and transport balance, exciton migration pathways, and interactions between the light-emitting layers.

Korean Patent Application Laid-Open Nos. 10-2022-0069028 and 10-2022-0069030 disclose an organic electroluminescent device including a plurality of light-emitting layers and light-emitting materials applied thereto, respectively. However, this prior art generally proposes only structures composed of two layers, namely a first light-emitting layer and a second light-emitting layer, and does not provide specific configurations or technical considerations for structures in which three or more light-emitting layers are stacked. In particular, the prior art lacks advanced designs regarding combinations of host compounds between light-emitting layers and efficiency enhancement and color tuning characteristics resulting from interactions therebetween. Accordingly, technical limitations still remain in terms of maximizing luminous efficiency, improving color purity, and stably securing device lifespan.

### DISCLOSURE OF INVENTION

### Problems to be Solved

An object of the present invention is to provide an organic electroluminescent device exhibiting higher current efficiency and superior lifespan characteristics as compared with conventional organic electroluminescent devices.

### Solution to Problems

As a result of intensive studies conducted to solve the above technical problem, the present inventors have found that an organic electroluminescent device comprising: a first electrode; a second electrode facing the first electrode; and a first light-emitting layer, a second light-emitting layer, and a third light-emitting layer sequentially included between the first electrode and the second electrode and adjacent to one another, wherein the first light-emitting layer is positioned closer to the first electrode, the third light-emitting layer is positioned closer to the second electrode, each of the first light-emitting layer, the second light-emitting layer, and the third light-emitting layer comprises at least one host compound and at least one dopant compound, and at least one pair of adjacent light-emitting layers comprises different host compounds, achieves the above-described object, thereby completing the present invention.

### Advantageous Effects of Invention

The organic electroluminescent device according to the present invention exhibits high current efficiency and superior lifespan characteristics.

### EMBODIMENTS OF INVENTION

Hereinafter, the present disclosure will be described in detail. However, the following description is intended to explain the invention, and is not meant in any way to restrict the scope of the invention.

The organic electroluminescent device according to the present disclosure comprises: a first electrode; a second electrode facing the first electrode; and a first light-emitting layer, a second light-emitting layer, and a third light-emitting layer sequentially included between the first electrode and the second electrode and adjacent to one another, wherein the first light-emitting layer is positioned closer to the first electrode, the third light-emitting layer is positioned closer to the second electrode, each of the first light-emitting layer, the second light-emitting layer, and the third light-emitting layer comprises at least one host compound and at least one dopant compound, and at least one pair of adjacent light-emitting layers comprises different host compounds.

The organic electroluminescent device according to the present disclosure comprises: a first electrode; a second electrode facing the first electrode; and two or more light-emitting units disposed between the first electrode and the second electrode and comprising at least one light-emitting layer, wherein at least one of the light-emitting units sequentially comprises a first light-emitting layer, a second light-emitting layer, and a third light-emitting layer which are adjacent to one another.

Herein, the term “compound” or “organic electroluminescent compound” means a compound that may be used in an organic electroluminescent device, and may be included in any material layer constituting the organic electroluminescent device, as necessary.

Herein, the term “dopant compound” means a compound that emits light in a light-emitting layer of an organic electroluminescent device, and performs a function of inducing emission of light at a specific wavelength by utilizing energy of excitons. In general, a dopant compound is included in a light-emitting layer at a low concentration, and may receive energy from a host compound in the light-emitting layer to be responsible for fluorescence emission or phosphorescence emission. The dopant compound plays an important role in controlling color purity and luminous efficiency of the device, and may be classified as a fluorescent dopant, a phosphorescent dopant, or a thermally activated delayed fluorescence (TADF) dopant, depending on the type used.

Herein, the term “host compound” means a material that supports a dopant compound in a light-emitting layer and serves as a matrix that assists charge injection and exciton formation.

Herein, the term “organic electroluminescent material” means a material that can be used in an organic electroluminescent device, may comprise one or more kinds of compounds, and, as necessary, may be included in any layer constituting the organic electroluminescent device. For example, the organic electroluminescent material may be a hole injection material, a hole transport material, a hole auxiliary material, a light-emitting auxiliary material, an electron-blocking material, a light-emitting material (including a host material and a dopant material), an electron buffer material, a hole-blocking material, an electron transport material, or an electron injection material, etc.

Herein, the term “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g., after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two compounds are comprised in one light-emitting layer, the at least two compounds may be mixture-evaporated to form a layer or may be individually and simultaneously co-evaporated to form a layer.

Herein, “(C₁-C₃₀)alkyl” is meant to be a linear or branched alkyl having 1 to 30 carbon atoms constituting the chain, in which the number of carbon atoms is preferably 1 to 20, and more preferably 1 to 10. The above alkyl may include methyl, ethyl, n-propyl, isopropyl, n-butyl, isobutyl, tert-butyl, sec-butyl, etc. Herein, “(C₃-C₃₀)cycloalkyl” or “(C₃-C₃₀)cycloalkylene” means a monocyclic or polycyclic hydrocarbon in which the number of ring framework carbons is 3 to 30; herein, it is preferably 3 to 20, and more preferably 3 to 7. Examples of the cycloalkyl include cyclopropyl, cyclobutyl, cyclopentyl, cyclohexyl, cyclopentylmethyl, and cyclohexylmethyl. Herein, “(3- to 7-membered)heterocycloalkyl” is meant to be a cycloalkyl ring having 3 to 7 ring framework atoms; herein, the number of carbons is preferably 5 to 7, and it includes one or more heteroatoms selected from the group consisting of B, N, O, S, Si, and P, preferably O, S, and N. The heterocycloalkyl includes, for example, tetrahydrofuran, pyrrolidine, thiolane, and tetrahydropyran, etc. Herein, “(C₆-C₃₀)aryl(ene)” means a monocyclic or fused-ring radical derived from an aromatic hydrocarbon in which the number of ring framework carbons is 6 to 30, and may be partially saturated; herein, the number of ring framework carbons is preferably 6 to 20, and more preferably 6 to 15. The aryl includes those having a spiro structure. Examples of the aryl specifically may be phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl, spiro[fluoren-fluoren]yl, spiro[fluoren-benzofluoren]yl, azulenyl, tetramethyl-dihydrophenanthrenyl, etc. More specifically, the aryl may be o-tolyl, m-tolyl, p-tolyl, 2,3-xytyl, 3,4-xytyl, 2,5-xytyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-8-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-8-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-8-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-8-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-8-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-8-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. Herein, “(3- to 30-membered)heteroaryl(ene)” means an aryl group or an arylene group in which the number of ring framework atoms is 3 to 30 and which includes one or more heteroatoms selected from the group consisting of B, N, O, S, Si, P, and Se. Herein, the number of ring framework atoms is preferably 5 to 25. The number of heteroatoms is preferably 1 to 4, and the ring may be monocyclic or a fused-ring system condensed with one or more benzene rings, and may be partially saturated. In addition, in the present disclosure, the heteroaryl or heteroarylene also includes forms in which one or more heteroaryl or aryl groups are linked to a heteroaryl group by a single bond. Examples of the heteroaryl specifically may be a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthyridinyl, benzofuropyrimidinyl, naphthofuropyrimidinyl, benzothienoquinolinyl, benzothienoquinazolinyl, benzothienonaphthyridinyl, benzothienopyrimidinyl, naphthothienopyrimidinyl, pyrimidoindolyl, benzopyrmidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyrdinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthrdinyl, 4-phenanthrdinyl, 6-phenanthridinyl, 7-phenanthrdinyl, 8-phenanthrdinyl, 9-phenanthridinyl, 10-phenanthrdinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho[1,2-b]benzofuranyl, 2-naphtho[1,2-b]benzofuranyl, 3-naphtho[1,2-b]benzofuranyl, 4-naphtho[1,2-b]benzofuranyl, 5-naphtho[1,2-b]benzofuranyl, 6-naphtho[1,2-b]benzofuranyl, 7-naphtho[1,2-b]benzofuranyl, 8-naphtho[1,2-b]benzofuranyl, 9-naphtho[1,2-b]benzofuranyl, 10-naphtho[1,2-b]benzofuranyl, 1-naphtho[2,3-b]benzofuranyl, 2-naphtho[2,3-b]benzofuranyl, 3-naphtho[2,3-b]benzofuranyl, 4-naphtho[2,3-b]benzofuranyl, 5-naphtho[2,3-b]benzofuranyl, 6-naphtho[2,3-b]benzofuranyl, 7-naphtho[2,3-b]benzofuranyl, 8-naphtho[2,3-b]benzofuranyl, 9-naphtho[2,3-b]benzofuranyl, 10-naphtho[2,3-b]benzofuranyl, 1-naphtho[2,1-b]benzofuranyl, 2-naphtho[2,1-b]benzofuranyl, 3-naphtho[2,1-b]benzofuranyl, 4-naphtho[2,1-b]benzofuranyl, 5-naphtho[2,1-b]benzofuranyl, 6-naphtho[2,1-b]benzofuranyl, 7-naphtho[2,1-b]benzofuranyl, 8-naphtho[2,1-b]benzofuranyl, 9-naphtho[2,1-b]benzofuranyl, 10-naphtho[2,1-b]benzofuranyl, 1-naphtho[1,2-b]benzothiophenyl, 2-naphtho[1,2-b]benzothiophenyl, 3-naphtho[1,2-b]benzothiophenyl, 4-naphtho[1,2-b]benzothiophenyl, 5-naphtho[1,2-b]benzothiophenyl, 6-naphtho[1,2-b]benzothiophenyl, 7-naphtho[1,2-b]benzothiophenyl, 8-naphtho[1,2-b]benzothiophenyl, 9-naphtho[1,2-b]benzothiophenyl, 10-naphtho[1,2-b]benzothiophenyl, 1-naphtho[2,3-b]benzothiophenyl, 2-naphtho[2,3-b]benzothiophenyl, 3-naphtho[2,3-b]benzothiophenyl, 4-naphtho[2,3-b]benzothiophenyl, 5-naphtho[2,3-b]benzothiophenyl, 1-naphtho[2,1-b]benzothiophenyl, 2-naphtho[2,1-b]benzothiophenyl, 3-naphtho[2,1-b]benzothiophenyl, 4-naphtho[2,1-b]benzothiophenyl, 5-naphtho[2,1-b]benzothiophenyl, 6-naphtho[2,1-b]benzothiophenyl, 7-naphtho[2,1-b]benzothiophenyl, 8-naphtho[2,1-b]benzothiophenyl, 9-naphtho[2,1-b]benzothiophenyl, 10-naphtho[2,1-b]benzothiophenyl, 2-benzofuro[3,2-d]pyrimidinyl, 6-benzofuro[3,2-d]pyrmidinyl, 7-benzofuro[3,2-d]pyrimidinyl, 8-benzofuro[3,2-d]pyrmidinyl, 9-benzofuro[3,2-d]pyrmidinyl, 2-benzothio[3,2-d]pyrmidinyl, 6-benzothio[3,2-d]pyrmidinyl, 7-benzothio[3,2-d]pyrmidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “heteroaryl(ene)” can be classified into a heteroaryl(ene) with electronic properties and a heteroaryl(ene) with hole properties. A heteroaryl(ene) with electronic properties is a substituent with relatively abundant electrons in the parent nucleus, and for example, it may be a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. A heteroaryl(ene), which has hole properties, is a substituent with a relative lack of electrons in the parent nucleus, and for example, it may be a substituted or unsubstituted carbazolyl, a substituted or unsubstituted dibenzofuranyl, or a substituted or unsubstituted dibenzothiophenyl. Herein, the term “a fused ring of a (C₃-C₃₀)aliphatic ring and a (C₆-C₃₀)aromatic ring” means a ring formed by fusing at least one aliphatic ring having 3 to 30 ring backbone carbon atoms in which the number of carbon atoms is preferably 3 to 25, more preferably 3 to 18, and at least one aromatic ring having 6 to 30 ring backbone carbon atoms in which the number of carbon atoms is preferably 6 to 25, more preferably 6 to 18. For example, the fused ring may be a fused ring of at least one benzene and at least one cyclohexane, or a fused ring of at least one naphthalene and at least one cyclopentane, etc. Herein, the carbon atoms in the fused ring of a (C₃-C₃₀)aliphatic ring and a (C₆-C₃₀)aromatic ring may be replaced with at least one heteroatom selected from B, N, O, S, Si, and P, preferably at least one heteroatom selected from N, O, and S. The “halogen” in the present disclosure includes F, Cl, Br, and I.

In addition, “ortho-” (“o-”), “meta-” (“m-”), and “para-” (“p-”) are meant to signify the substitution position of all substituents. An ortho-configuration describes a compound with substituents which are adjacent to one another, e.g., at the 1 and 2 positions on benzene. A meta-configuration indicates the next substitution position of the immediately adjacent substitution position, e.g., a compound with substituents at the 1 and 3 positions on benzene. A para-configuration indicates the next substitution position from the meta-position, e.g., a compound with substituents at the 1 and 4 positions on benzene.

Herein, the term “a ring formed in linking to an adjacent substituent” means a substituted or unsubstituted 3- to 30-membered mono- or polycyclic, alicyclic, aromatic ring, or a combination thereof, which is formed by two or more adjacent substituents being linked or fused together; preferably, it may be a substituted or unsubstituted 3- to 26-membered monocyclic or polycyclic alicyclic ring, an aromatic ring, or a combination thereof. The formed ring may include one or more heteroatoms selected from B, N, O, S, Si, and P, preferably one or more heteroatoms selected from N, O, and S. According to one embodiment, the number of ring framework atoms is 5- to 20-membered, and according to another embodiment, the number of ring framework atoms is 5- to 15-membered. By way of example, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, or a substituted or unsubstituted carbazole ring.

In addition, “substituted or unsubstituted” as described herein means that “substituted” refers to a case where a hydrogen atom in a functional group is replaced by another atom or another functional group (i.e., a substituent). Unless otherwise specified, the substituent(s) can, without limitation, replace hydrogens at positions in which substitution by a substituent is possible, and, where two or more hydrogen atoms in a given functional group are respectively replaced by substituents, the respective substituents may be the same as or different from one another. The maximum number of substituents that can be introduced into a given functional group may be the sum of the substitutable valences of the respective atoms constituting the functional group.

When a substituent is not shown in the chemical formula or the compound structure of the present disclosure, it may signify that all positions that may be present as substituents are hydrogen or deuterium. That is, in the case of deuterium, an isotope of hydrogen, some of the hydrogen atoms may be deuterium, which is an isotope; and in this case, the content of deuterium may be 0% to 100%. In the case where the substituent is not shown in the chemical formula or the compound structure of the present disclosure, when deuterium is not explicitly excluded, hydrogen and deuterium may be mixed and used in the compound, such as when the content of deuterium is 0%, the content of hydrogen is 100%, and all substituents are hydrogen. The deuterium is an element having a deuteron composed of one proton and one neutron as an atomic nucleus, which is one of the isotopes of hydrogen, and may be represented by hydrogen-2, and the element symbol may be D or ²H. Although the isotope has the same atomic number (Z), an isotope having a different mass number (A) means the same number of protons and the number of neutrons may also be interpreted as an element having different numbers.

Herein, “combinations thereof” signifies that one or more components of the corresponding list are combined to form a known or chemically stable arrangement that a person skilled in the art could conceive of from the corresponding list. For example, alkyl and deuterium may be combined to form partially or entirely deuterated alkyl groups; halogen and alkyl may be combined to form halogenated alkyl substituents; and halogen, alkyl, and aryl may be combined to form halogenated arylalkyl. For example, preferred combinations of substituents may include up to 50 atoms excluding hydrogen and deuterium, or include up to 40 atoms excluding hydrogen and deuterium, or include up to 30 atoms excluding hydrogen and deuterium, or in many cases, preferred combinations of substituents may include up to 20 atoms excluding hydrogen and deuterium.

In the formula of the present disclosure, when multiple substituents are indicated by the same symbol, each of these substituents represented by the same symbol may be the same as or different from one another.

Hereinafter, an organic electroluminescent device according to one embodiment will be described in detail.

The organic electroluminescent device according to one embodiment of the present disclosure comprises: a first electrode; a second electrode; and a first light-emitting layer, a second light-emitting layer, and a third light-emitting layer sequentially included between the first electrode and the second electrode and adjacent to one another, wherein the first light-emitting layer is positioned closer to the first electrode, the third light-emitting layer is positioned closer to the second electrode, each of the first light-emitting layer, the second light-emitting layer, and the third light-emitting layer comprises at least one host compound and at least one dopant compound, and at least one pair of adjacent light-emitting layers comprises different host compounds.

In the organic electroluminescent device according to one embodiment, each of the first light-emitting layer, the second light-emitting layer, and the third light-emitting layer may comprise different host compounds from each other.

In the organic electroluminescent device according to one embodiment, the first light-emitting layer and the third light-emitting layer may comprise the same host compound. For example, the first light-emitting layer and the third light-emitting layer may comprise the same host compound, but may be different from the host compound comprised in the second light-emitting layer.

In the organic electroluminescent device according to one embodiment, at least one layer among the first light-emitting layer, the second light-emitting layer, and the third light-emitting layer may comprise a plurality of host materials. For example, the first light-emitting layer and the third light-emitting layer may comprise a single host compound, and the second light-emitting layer may comprise a plurality of host materials.

In the organic electroluminescent device according to one embodiment, at least two layers among the first light-emitting layer, the second light-emitting layer, and the third light-emitting layer may comprise a plurality of host materials, and for example, the plurality of host materials comprised in each layer may be the same, but their content ratios may be different from each other. For example, a weight ratio of a first host compound and a second host compound comprised in the plurality of host materials may be from about 1:99 to about 99:1, preferably from about 10:90 to about 90:10, more preferably from about 30:70 to about 70:30, still more preferably from about 40:60 to about 60:40, and most preferably about 50:50, and may be included in the light-emitting layer.

In the organic electroluminescent device according to one embodiment, the second light-emitting layer may comprise an anthracene compound substituted or unsubstituted with deuterium, as a host compound.

In the organic electroluminescent device according to one embodiment, the first light-emitting layer may comprise, as a host compound, a compound in which at least four rings are fused. For example, the first light-emitting layer may comprise, as a host compound, a compound in which at least four rings are fused, selected from pyrene, benzopyrene, benzanthracene, dibenzanthracene, benzochrysene, dibenzochrysene, phenanthrofuran, and benzophenanthrene.

In the organic electroluminescent device according to one embodiment, the third light-emitting layer may not comprise a compound having an anthracene skeleton.

The first light-emitting layer according to one embodiment may comprise a compound represented by the following Formula 1-1.

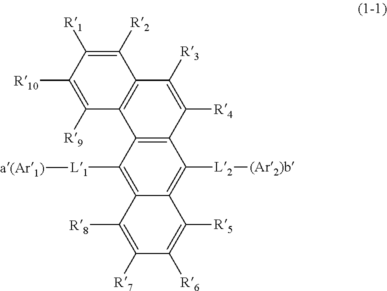

In Formula 1-1,
L′₁ and L′₂ each independently represent a single bond, a substituted or unsubstituted (C₆-C₃₀)arylene, or a substituted or unsubstituted (3- to 30-membered)heteroarylene;
Ar′₁ and Ar′₂ each independently represent a substituted or unsubstituted (C₆-C₃₀)aryl or a substituted or unsubstituted (3- to 30-membered)heteroaryl; provided that at least one of Ar′₁ and Ar′₂ comprises the following Formula A;

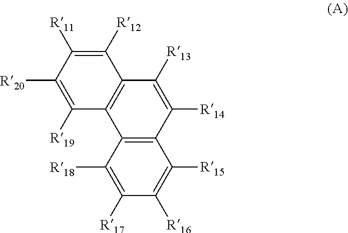

R′₁ to R′₂₀ each independently represent hydrogen, deuterium, halogen, cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino;
a′ and b′ each independently represent an integer of 1 or 2, and when a′ and b′ are 2, each Ar′₁ and Ar′₂ may be the same or different.

The second light-emitting layer according to one embodiment may comprise a compound represented by the following Formula 2-1.

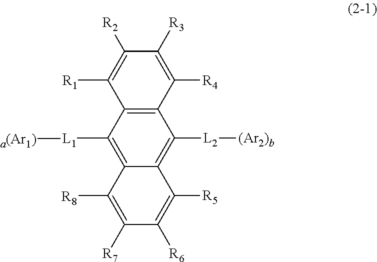

In Formula 2-1,
L₁ and L₂ each independently represent a single bond, a substituted or unsubstituted (C₆-C₃₀)arylene, or a substituted or unsubstituted (3- to 30-membered)heteroarylene;
Ar₁ and Ar₂ each independently represent a substituted or unsubstituted (C₆-C₃₀)aryl or a substituted or unsubstituted (3- to 30-membered)heteroaryl;
R₁ to R₈ each independently represent hydrogen, deuterium, halogen, cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)cycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino;
a and b each independently represent an integer of 1 or 2; and
when a and b are 2, each Ar₁ and Ar₂ may be the same or different.

The third light-emitting layer according to one embodiment may comprise any one selected from compounds represented by Formula 2-1, Formula 3-1, and Formula 3-2.

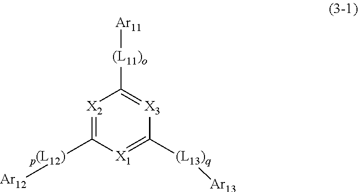

In Formula 3-1,
X₁ to X₃ each independently represent CR′ or N; provided that at least two of X₁ to X₃ are N;
R′ represents hydrogen or deuterium;
L₁₁ to L₁₃ each independently represent a single bond, a substituted or unsubstituted (C₆-C₃₀)arylene, or a substituted or unsubstituted (3- to 30-membered)heteroarylene;
Ar₁₁ to Ar₁₃ each independently represent a substituted or unsubstituted (C₆-C₃₀)aryl or a substituted or unsubstituted (3- to 30-membered)heteroaryl; and
o to q each independently represent 1 or 2, and when o to q are 2 or more, each of L₁₁ to L₁₃ may be the same or different.

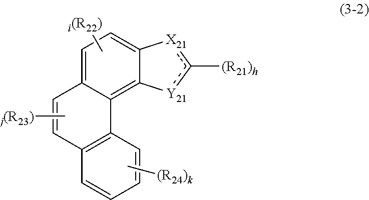

In Formula 3-2,
X₂₁ represents —N═, —NR₂₇—, —O—, or —S—, and Y₂₁ represents —N═, —NR₂₈—, —O—, or —S—; provided that, when X₂₁ is —N═, Y₂₁ is —NR₂₈—, —O—, or —S—, and when X₂₁, is —NR₂₇—, Y₂₁ is —N═, —O—, or —S—;
provided that cases in which both X₂₁ and Y₂₁ are —O—, both are —S—, and one of X₂₁ and Y₂₁ is —O— and the other is —S— are excluded;
R₂₁ represents a substituted or unsubstituted (C₆-C₃₀)aryl or a substituted or unsubstituted (3- to 30-membered)heteroaryl;
R₂₂ to R₂₄, R₂₇, and R₂₈ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₆-C₃₀)arylamino, or a substituted or unsubstituted (C₁-C₃₀)alkyl(C₆-C₃₀)arylamino; or may be linked to an adjacent substituent to form a ring;
h is 1, i and j are each independently 1 or 2, and k is an integer of 1 to 4; and
when i and j are 2 and k is 2 or more, each of R₂₂ to R₂₄ may be the same or different.

In one embodiment, in the compound represented by Formula 2-1 comprised in the third light-emitting layer, Ar₂ may be a carbazole group represented by the following Formula 3-11.

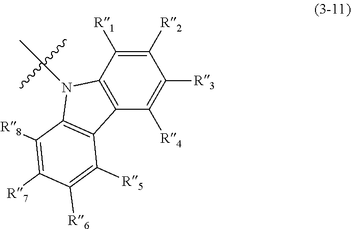

In Formula 3-11,
R″₁ to R″₈ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₆-C₃₀)arylamino, or a substituted or unsubstituted (C₁-C₃₀)alkyl(C₆-C₃₀)arylamino; or may be linked to an adjacent substituent to form a ring; and
[symbol] represents a position bonded to L₂.

In the organic electroluminescent device according to one embodiment, the triplet energy of the host compound comprised in the third light-emitting layer satisfies being greater than the triplet energy of the host compound comprised in the second light-emitting layer. For example, a difference in triplet energy between the host compounds comprised in the third light-emitting layer comprising the compound of Formula 3-1 and the second light-emitting layer may be preferably 0.8 eV or more, and more preferably 1.0 eV or more. Such a difference in triplet energy may contribute to improving light-emitting performance and lifespan of the device by preventing energy back-transfer and suppressing a decrease in luminous efficiency.

The triplet energy is a simulation value obtained using a density functional theory (DFT) method, and Gaussian16 was used as simulation software. With respect to a three-dimensional structure of a compound to be measured, various conformers were generated and geometry optimization was performed, and among these, a structure having the lowest energy was selected, and a first triplet, a second triplet, and a first singlet were calculated by time-dependent density functional theory (TD-DFT). The method and basis set used for the calculation were B3LYP/6-31g*, and the same conditions were used for both geometry optimization and triplet and singlet calculations.

In one embodiment, the third light-emitting layer comprising the compound of Formula 3-1 may have a first triplet energy (T₁) of 2.7 eV or more, preferably 2.8 eV or more, and more preferably 2.9 eV or more.

In addition, the third light-emitting layer comprising the compound of Formula 3-1 may comprise a compound in which a difference (ΔE_{ST}) between a first singlet energy (S₁) and a second triplet energy (T₂) is 0.2 eV or less. For example, the difference (ΔE_{ST}) between the first singlet energy and the second triplet energy may be preferably 0.15 eV or less, and more preferably 0.1 eV or less. As the ΔE_{ST} is smaller, efficient reverse intersystem crossing (RISC) is possible, thereby improving thermally activated delayed fluorescence (TADF) emission characteristics.

The third light-emitting layer according to one embodiment may comprise, as a host compound, a compound represented by Formula 3-1.

In the organic electroluminescent device according to one embodiment, at least one layer among the first light-emitting layer, the second light-emitting layer, and the third light-emitting layer may comprise, as a dopant compound, a compound comprising a boron (B) atom substituted or unsubstituted with deuterium.

In the organic electroluminescent device according to one embodiment, the first light-emitting layer, the second light-emitting layer, and the third light-emitting layer do not comprise, as a dopant compound, a thermally activated delayed fluorescence (TADF) dopant other than a compound comprising a boron (B) atom.

In the organic electroluminescent device according to one embodiment, at least one layer among the first light-emitting layer, the second light-emitting layer, and the third light-emitting layer may comprise a phosphorescent dopant, and as one embodiment, a phosphorescent dopant may be further comprised together with the dopant compound comprising a boron (B) atom. For example, the phosphorescent dopant comprised in the light-emitting layer may be used as an auxiliary dopant.

The organic electroluminescent device according to one embodiment may have the first light-emitting layer, the second light-emitting layer, and the third light-emitting layer all as blue light-emitting layers.

According to one embodiment, a dopant compound applied to the organic electroluminescent device may be a compound represented by the following Formula 100, but is not limited thereto.

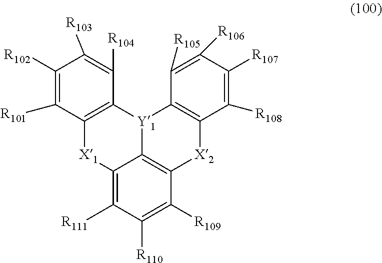

In Formula 100,
R₁₀₁ to R₁₁₁ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′—N—(Ar′₄)(Ar′₅); or may be linked to an adjacent substituent to form a ring;
Y′₁ represents B;
X′₁ and X′ each independently represent NR′;
R′ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄—N—(Ar′₄)(Ar′₅); or may be linked to one or more of R₁₀₁, R₁₀₈, R₁₀₉, and R₁₁₁ to form a ring;
L′₄ represents a single bond, a substituted or unsubstituted (C₆-C₃₀)arylene, or a substituted or unsubstituted (3- to 30-membered)heteroarylene; and
Ar′₄ and Ar′₅ each independently represent hydrogen, a substituted or unsubstituted (C₁-C₃₀)alkyl, a substituted or unsubstituted (C₂-C₃₀)alkenyl, a substituted or unsubstituted fused ring of a (C₃-C₃₀)aliphatic ring and a (C₆-C₃₀)aromatic ring, a substituted or unsubstituted (C₆-C₃₀)aryl, or a substituted or unsubstituted (3- to 30-membered)heteroaryl.

Preferably, R₁₀₁ to R₁₁₁ each independently may be hydrogen, deuterium, a substituted or unsubstituted (C₁-C₂₀)alkyl, a substituted or unsubstituted (C₆-C₂₅)aryl, a substituted or unsubstituted (5- to 20-membered)heteroaryl, or -L′₄—N—(Ar′₄)(Ar′₅); or may be linked to an adjacent substituent to form a ring.

More preferably, R₁₀₁ to R₁₁₁ each independently may be hydrogen; deuterium; an unsubstituted (C₁-C₁₀)alkyl; (C₆-C₁₈)aryl substituted or unsubstituted with one or more selected from (C₁-C₁₀)alkyl, (13- to 18-membered)heteroaryl, and di(C₆-C₁₈)arylamino; (5- to 18-membered)heteroaryl substituted or unsubstituted with one or more (C₁-C₁₀)alkyl; or -L′₄—N—(Ar′₄)(Ar′₅); or may be linked to an adjacent substituent to form a ring. For example, R₁₀₁ to R₁₁₁ each independently may be hydrogen, methyl, tert-butyl, a substituted or unsubstituted phenyl, biphenyl, terphenyl, triphenylenyl, carbazolyl, phenoxazinyl, phenothiazinyl, dimethylacridinyl, dimethylxanthenyl, diphenylamino unsubstituted or substituted with at least one of methyl and diphenylamino, phenylnaphthylamino, dibiphenylamino, phenylamino substituted with phenylcarbazolyl or dibenzofuranyl, (17- to 21-membered)heteroaryl substituted with at least one of methyl and phenyl, or may be linked to the adjacent substituents to form a benzene ring, an indole ring substituted with at least one of phenyl and diphenylamino, a benzofuran ring, a benzothiophene ring, or a 19-membered heterocyclic ring substituted with at least one methyl. The substituent of the substituted phenyl may be at least one of methyl, carbazolyl, dibenzofuranyl, diphenylamino, phenoxazinyl, phenothiazinyl, and dimethylacridinyl.

According to one embodiment, the compounds may be specifically exemplified by the following compounds, but are not limited thereto.

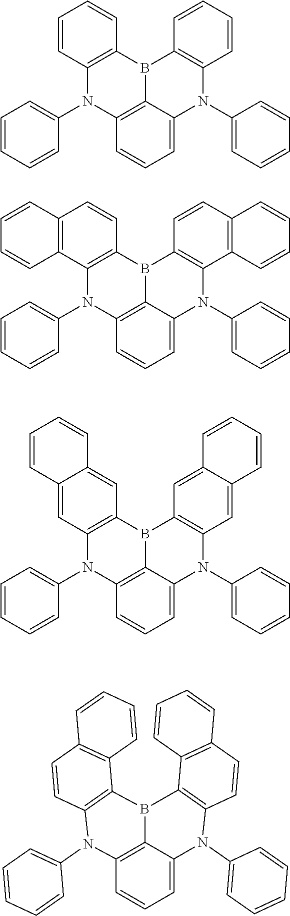

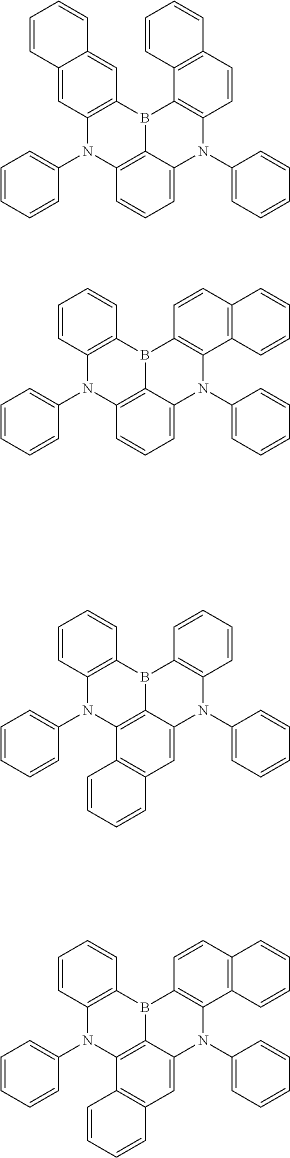 [SMILES: c1ccc(N2c3cc4ccccc4cc3B3c4c2cccc4N(c2ccccc2)c2ccc4ccccc4c23)cc1 ; c1ccc(N2c3ccccc3B3c4ccc5ccccc5c4N(c4ccccc4)c4cccc2c43)cc1 ; c1ccc(N2c3ccccc3B3c4ccccc4N(c4ccccc4)c4c3c2cc2ccccc42)cc1 ; c1ccc(N2c3cc4ccccc4c4c3B(c3ccccc3N4c3ccccc3)c3ccc4ccccc4c32)cc1]

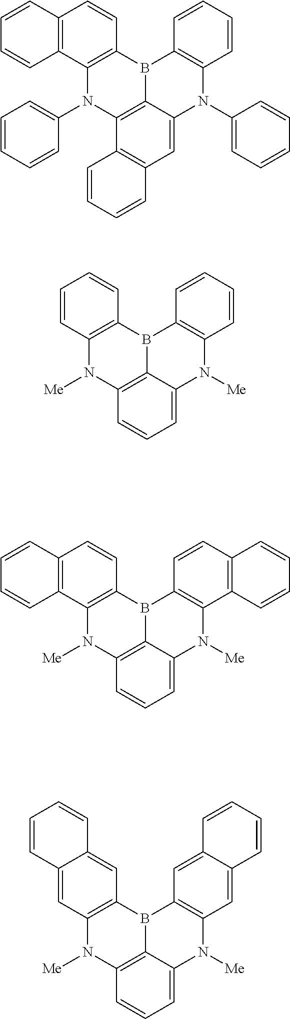 [SMILES: c1ccc(N2c3ccccc3B3c4ccc5ccccc5c4N(c4ccccc4)c4c3c2cc2ccccc42)cc1 ; CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32]

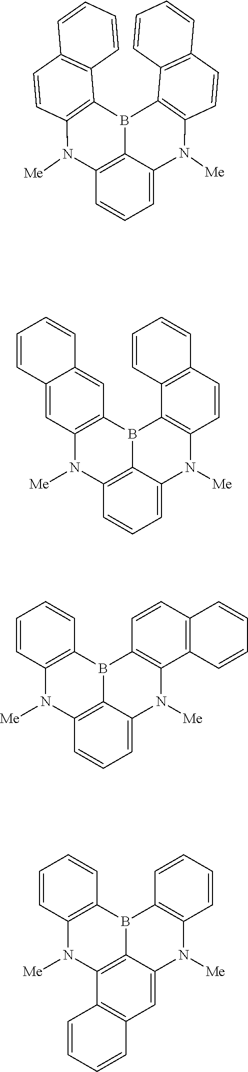 [SMILES: CN1c2cccc3c2B(c2c1ccc1ccccc21)c1c(ccc2ccccc12)N3C ; CN1c2cc3ccccc3cc2B2c3c1cccc3N(C)c1ccc3ccccc3c12 ; CN1c2ccccc2B2c3ccc4ccccc4c3N(C)c3cccc1c32 ; CN1c2ccccc2B2c3ccccc3N(C)c3c2c1cc1ccccc31]

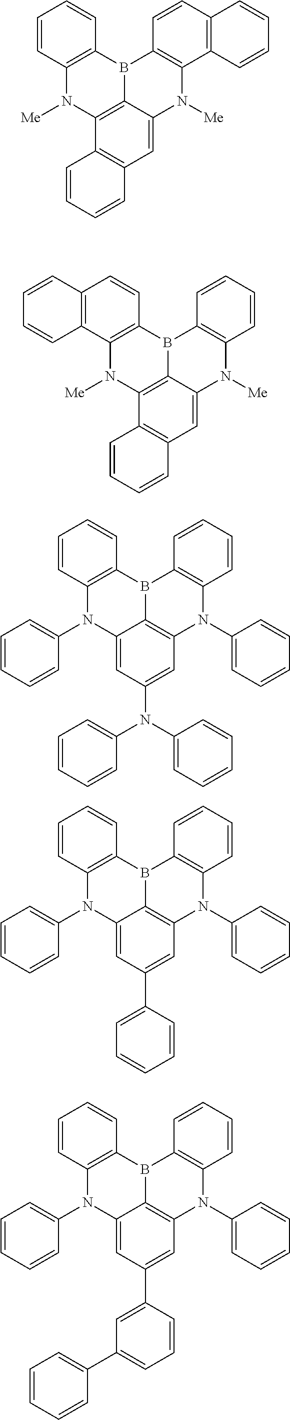

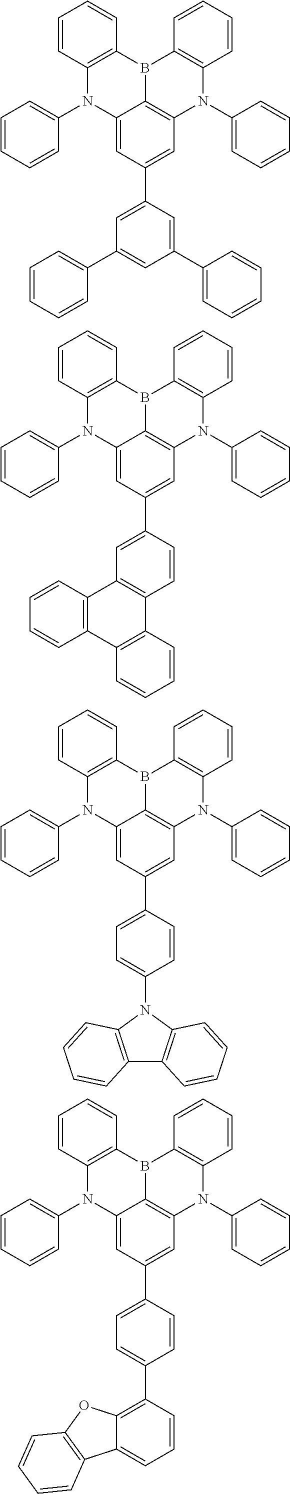

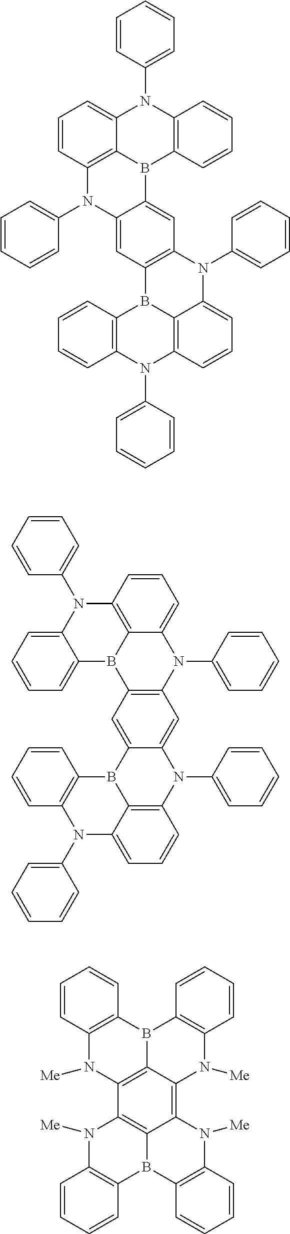 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1 ; CN1c2ccccc2B2c3ccccc3N(C)c3c2c1c1c2c3N(C)c3ccccc3B2c2ccccc2N1C]

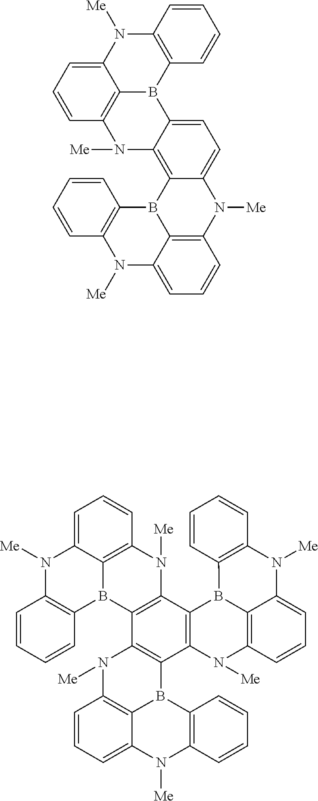 [SMILES: CN1c2ccccc2B2c3c1cccc3N(C)c1ccc3c(c12)N(C)c1cccc2c1B3c1ccccc1N2C ; CN1c2ccccc2B2c3c1cccc3N(C)c1c3c(c4c(c12)N(C)c1cccc2c1B4c1ccccc1N2C)N(C)c1cccc2c1B3c1ccccc1N2C]

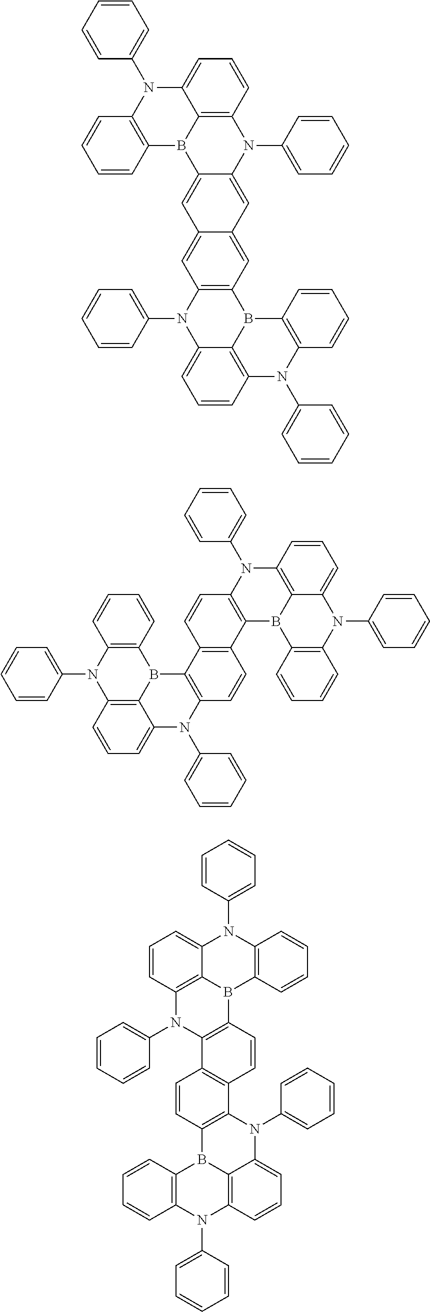

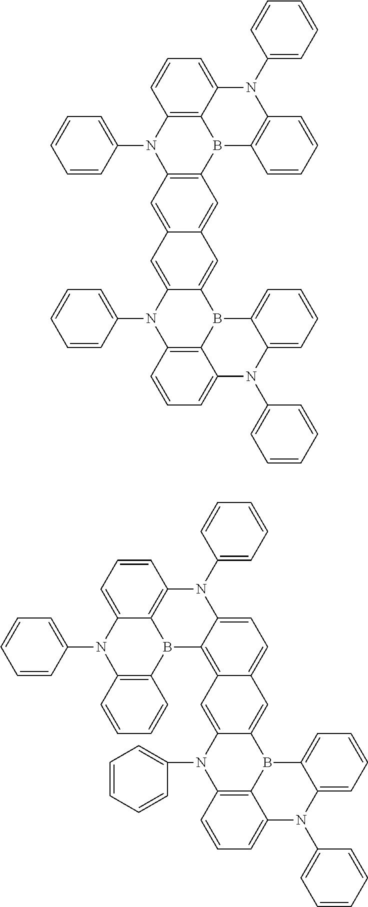

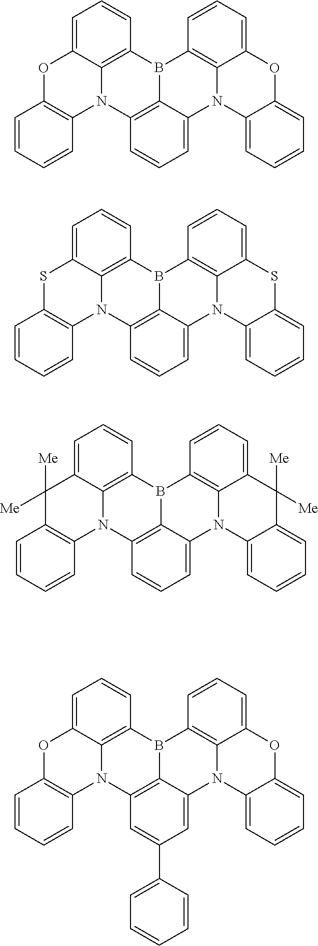 [SMILES: c1ccc2c(c1)Oc1cccc3c1N2c1cccc2c1B3c1cccc3c1N2c1ccccc1O3 ; c1ccc2c(c1)Sc1cccc3c1N2c1cccc2c1B3c1cccc3c1N2c1ccccc1S3 ; CC1(C)c2ccccc2N2c3cccc4c3B(c3cccc1c32)c1cccc2c1N4c1ccccc1C2(C)C ; c1ccc(-c2cc3c4c(c2)N2c5ccccc5Oc5cccc(c52)B4c2cccc4c2N3c2ccccc2O4)cc1]

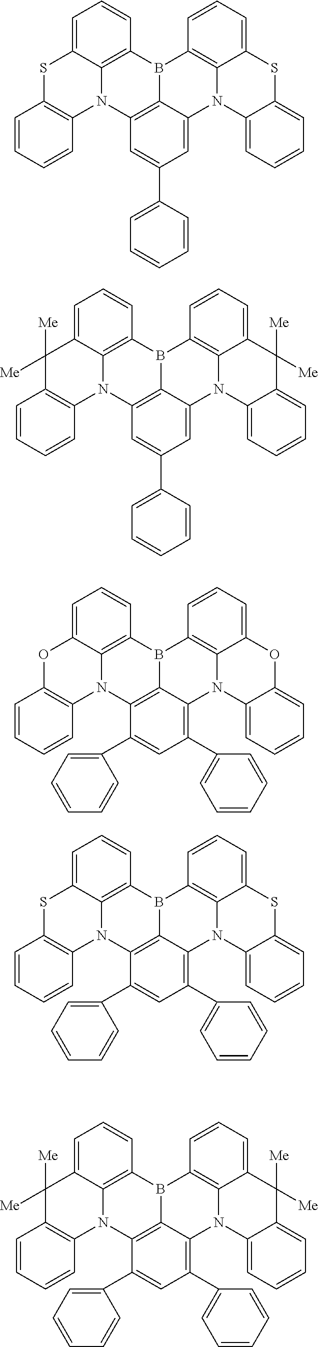

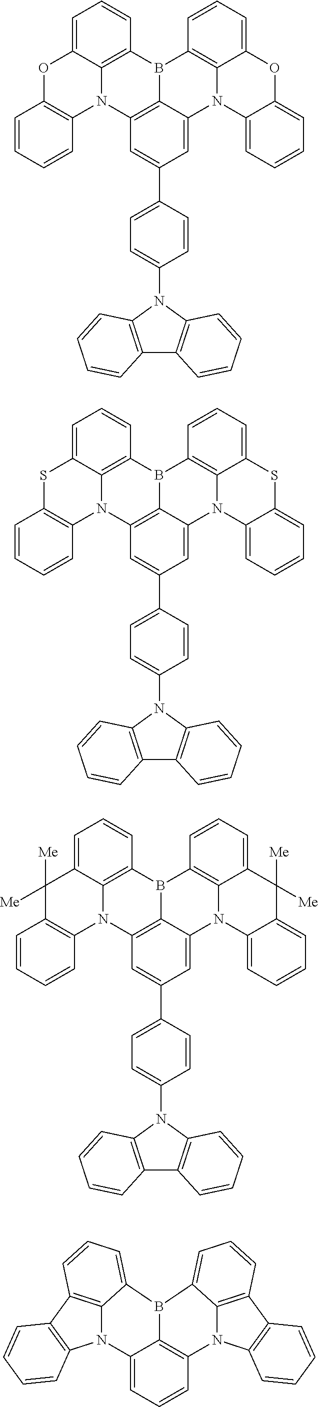

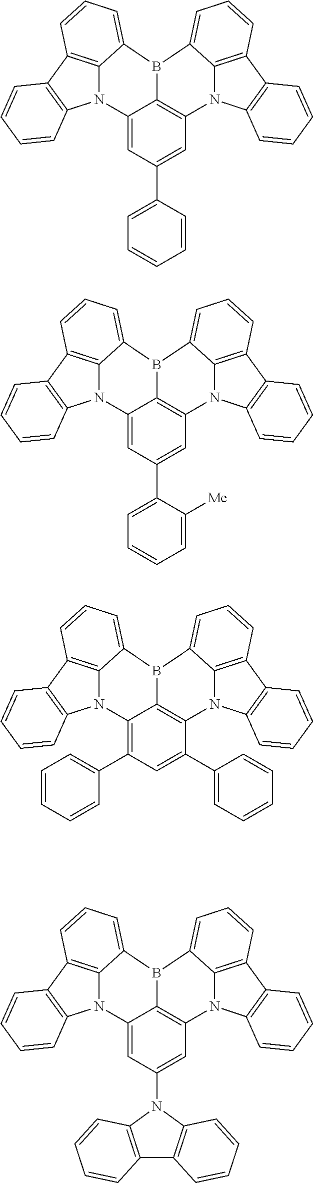 [SMILES: c1ccc(-c2cc3c4c(c2)-n2c5ccccc5c5cccc(c52)B4c2cccc4c5ccccc5n-3c24)cc1 ; Cc1ccccc1-c1cc2c3c(c1)-n1c4ccccc4c4cccc(c41)B3c1cccc3c4ccccc4n-2c13 ; c1ccc(-c2cc(-c3ccccc3)c3c4c2-n2c5ccccc5c5cccc(c52)B4c2cccc4c5ccccc5n-3c24)cc1 ; c1ccc2c(c1)c1ccccc1n2-c1cc2c3c(c1)-n1c4ccccc4c4cccc(c41)B3c1cccc3c4ccccc4n-2c13]

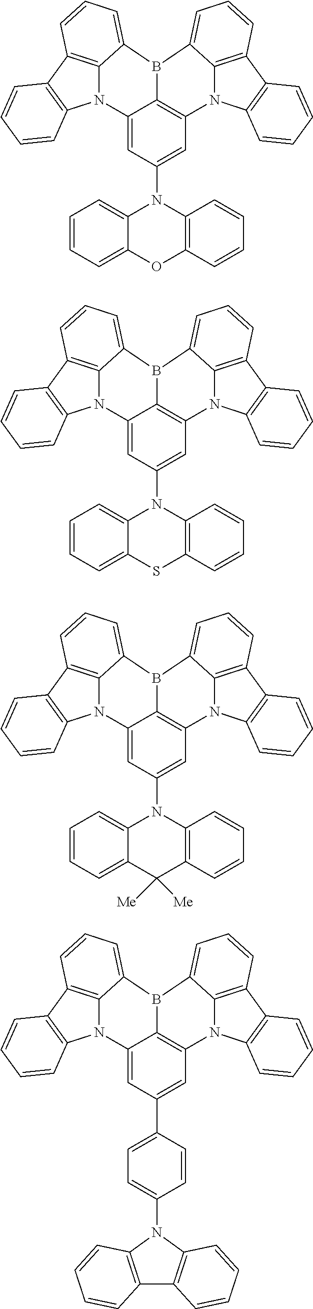

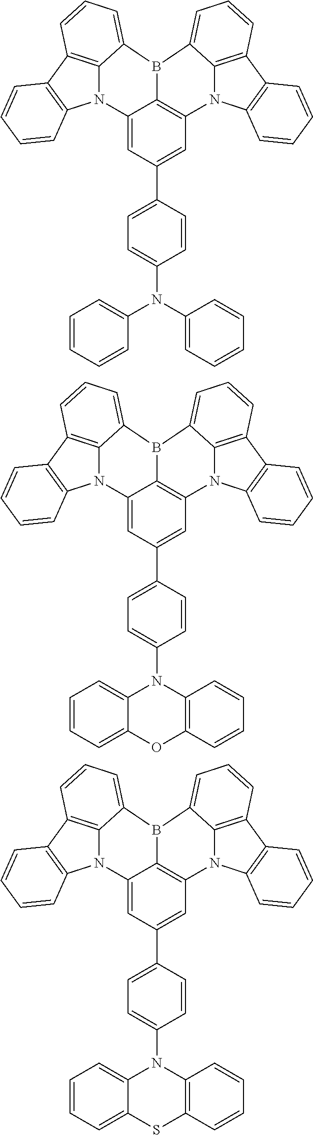

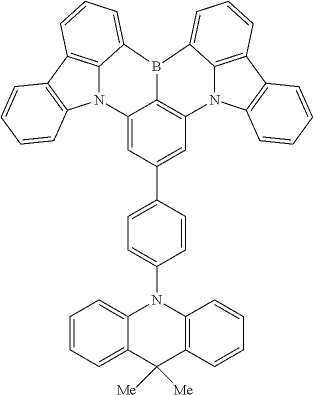 [SMILES: CC1(C)c2ccccc2N(c2ccc(-c3cc4c5c(c3)-n3c6ccccc6c6cccc(c63)B5c3cccc5c6ccccc6n-4c35)cc2)c2ccccc21]

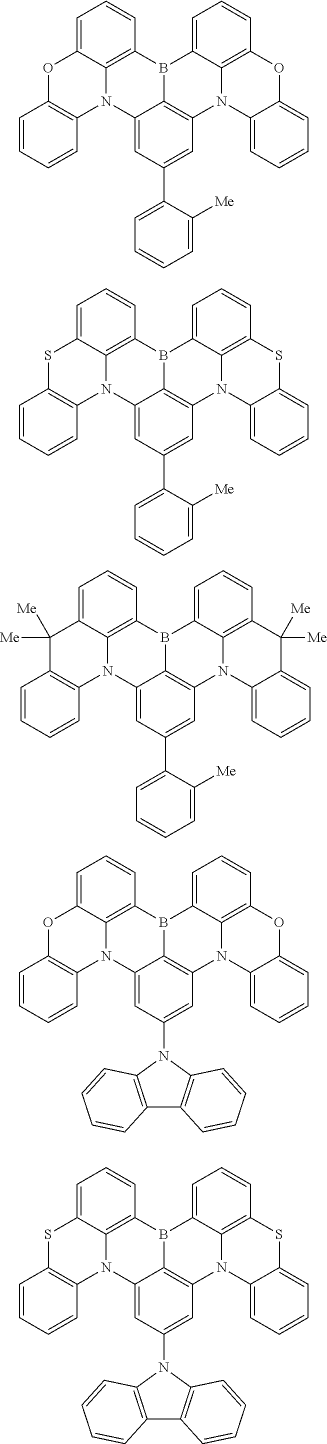

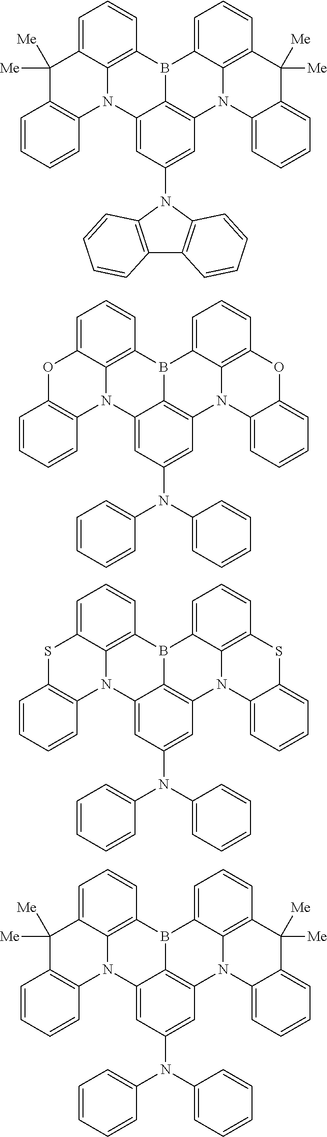

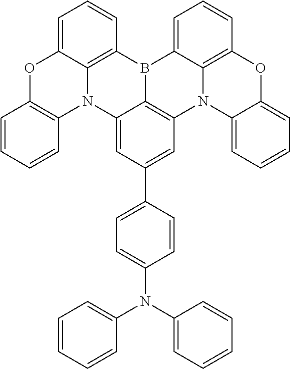 [SMILES: c1ccc(N(c2ccccc2)c2ccc(-c3cc4c5c(c3)N3c6ccccc6Oc6cccc(c63)B5c3cccc5c3N4c3ccccc3O5)cc2)cc1]

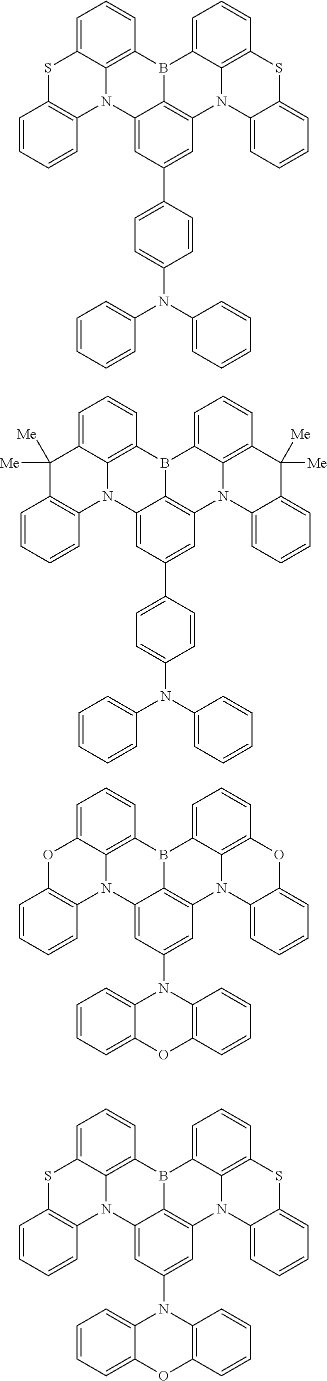

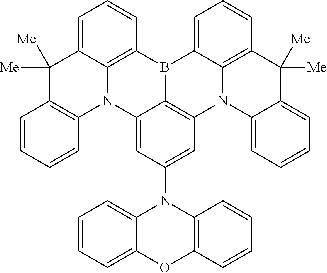 [SMILES: CC1(C)c2ccccc2N2c3cc(N4c5ccccc5Oc5ccccc54)cc4c3B(c3cccc1c32)c1cccc2c1N4c1ccccc1C2(C)C]

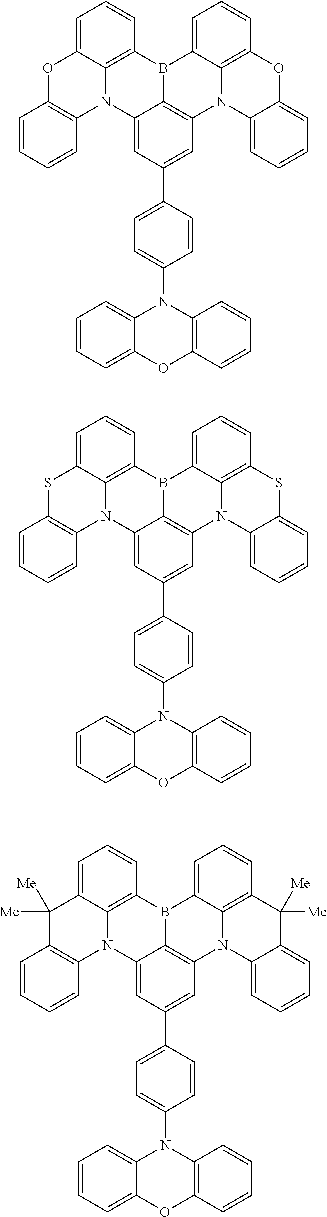 [SMILES: c1ccc2c(c1)Oc1ccccc1N2c1ccc(-c2cc3c4c(c2)N2c5ccccc5Oc5cccc(c52)B4c2cccc4c2N3c2ccccc2O4)cc1 ; c1ccc2c(c1)Oc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Oc6ccccc65)cc4)cc4c3B(c3cccc1c32)c1cccc2c1N4c1ccccc1C2(C)C]

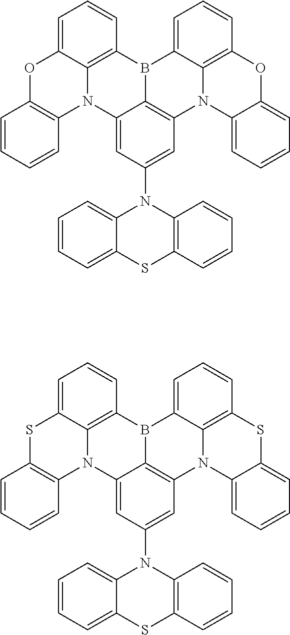 [SMILES: c1ccc2c(c1)Oc1cccc3c1N2c1cc(N2c4ccccc4Sc4ccccc42)cc2c1B3c1cccc3c1N2c1ccccc1O3 ; c1ccc2c(c1)Sc1ccccc1N2c1cc2c3c(c1)N1c4ccccc4Sc4cccc(c41)B3c1cccc3c1N2c1ccccc1S3]

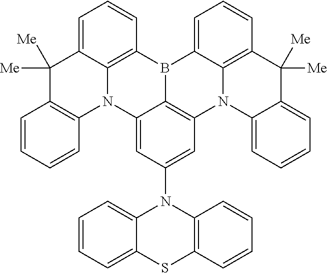 [SMILES: CC1(C)c2ccccc2N2c3cc(N4c5ccccc5Sc5ccccc54)cc4c3B(c3cccc1c32)c1cccc2c1N4c1ccccc1C2(C)C]

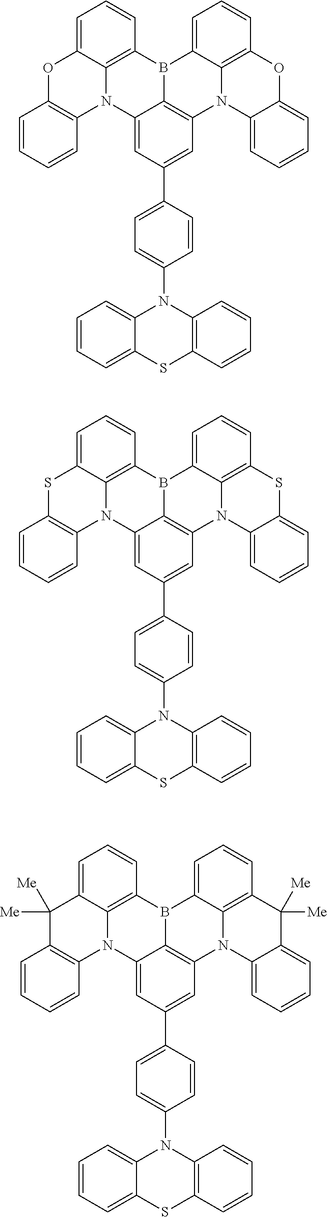 [SMILES: c1ccc2c(c1)Oc1cccc3c1N2c1cc(-c2ccc(N4c5ccccc5Sc5ccccc54)cc2)cc2c1B3c1cccc3c1N2c1ccccc1O3 ; c1ccc2c(c1)Sc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Sc6ccccc65)cc4)cc4c3B(c3cccc1c32)c1cccc2c1N4c1ccccc1C2(C)C]

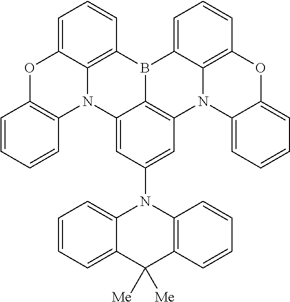 [SMILES: CC1(C)c2ccccc2N(c2cc3c4c(c2)N2c5ccccc5Oc5cccc(c52)B4c2cccc4c2N3c2ccccc2O4)c2ccccc21]

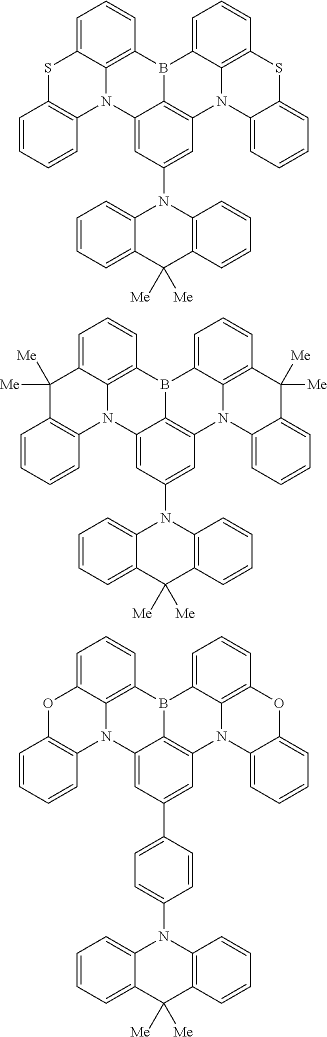

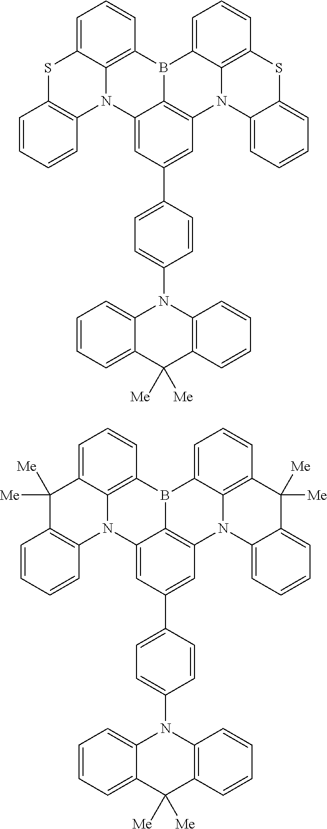 [SMILES: CC1(C)c2ccccc2N(c2ccc(-c3cc4c5c(c3)N3c6ccccc6Sc6cccc(c63)B5c3cccc5c3N4c3ccccc3S5)cc2)c2ccccc21 ; CC1(C)c2ccccc2N(c2ccc(-c3cc4c5c(c3)N3c6ccccc6C(C)(C)c6cccc(c63)B5c3cccc5c3N4c3ccccc3C5(C)C)cc2)c2ccccc21]

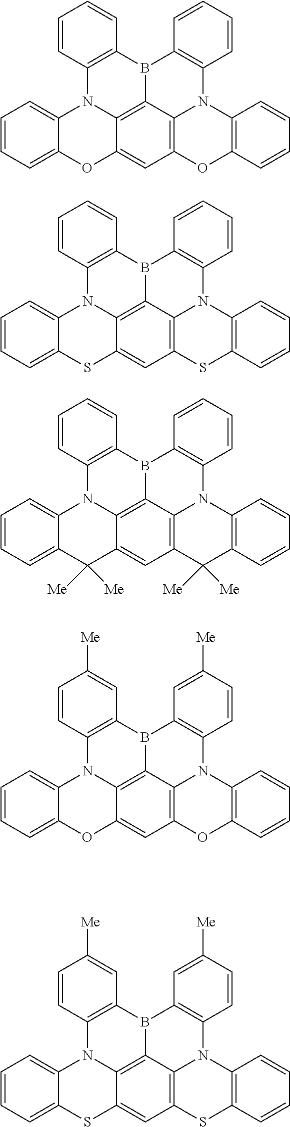

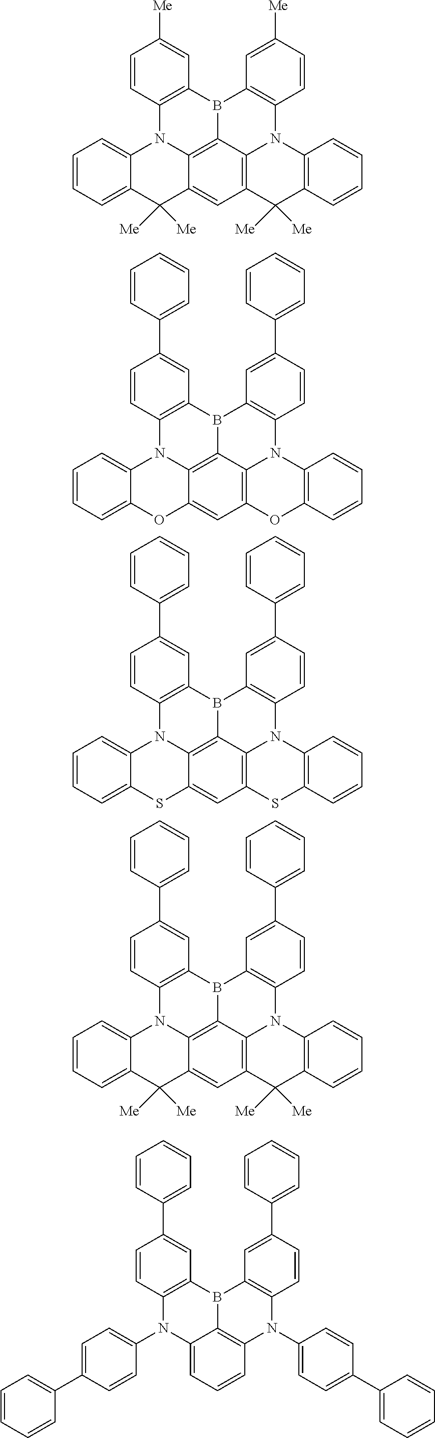

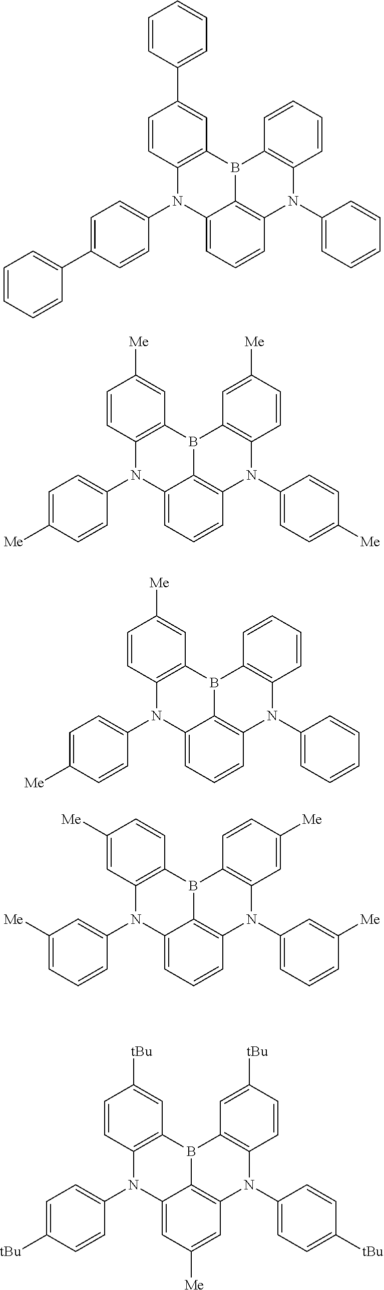

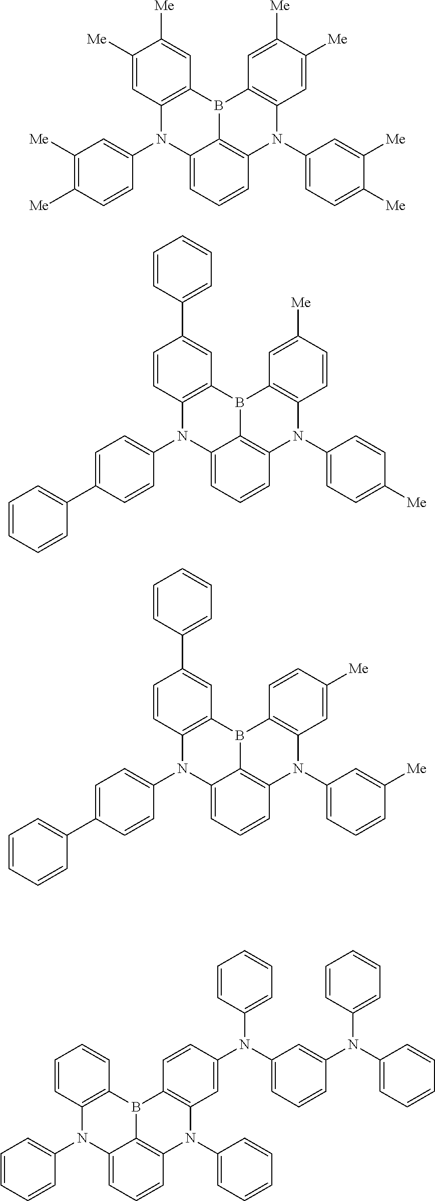 [SMILES: Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1 ; Cc1cccc(N2c3cc(C)ccc3B3c4cc(-c5ccccc5)ccc4N(c4ccc(-c5ccccc5)cc4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1]

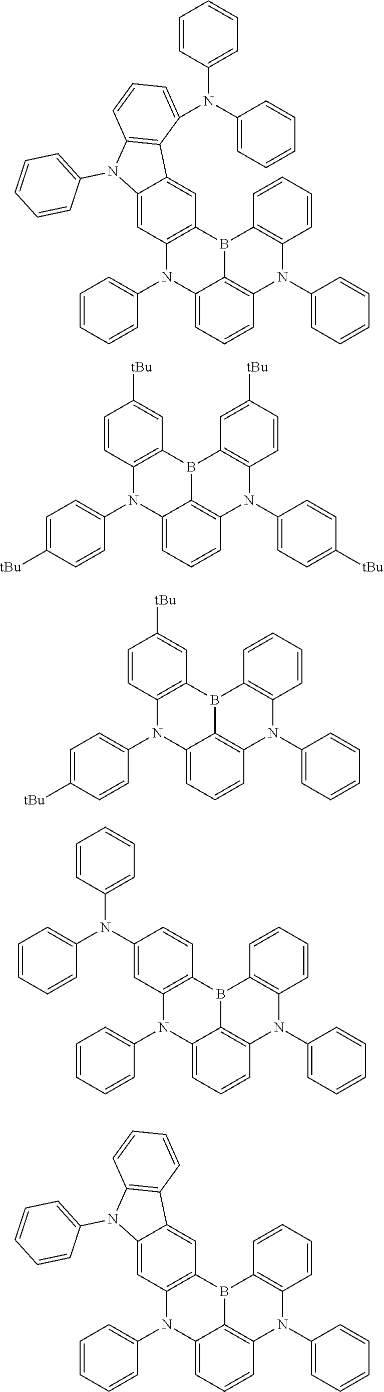

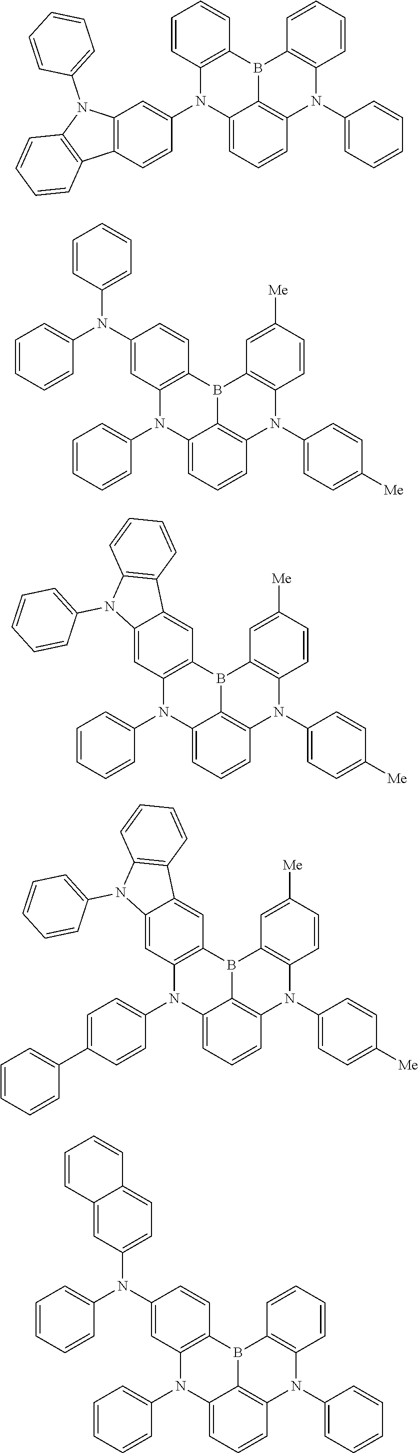

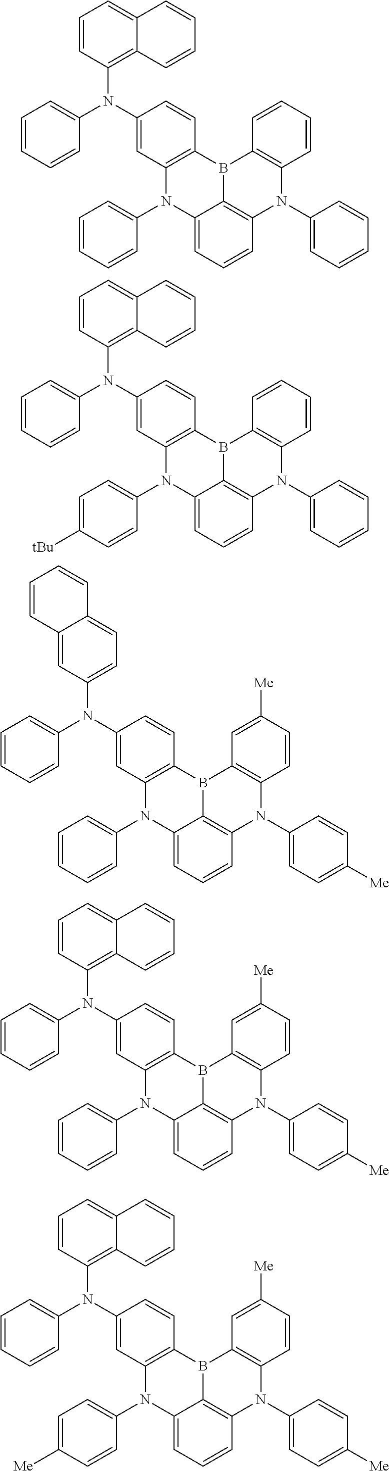

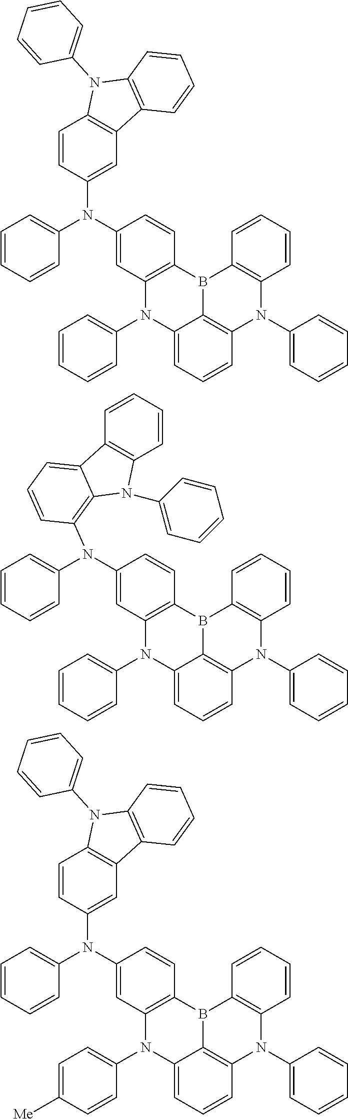

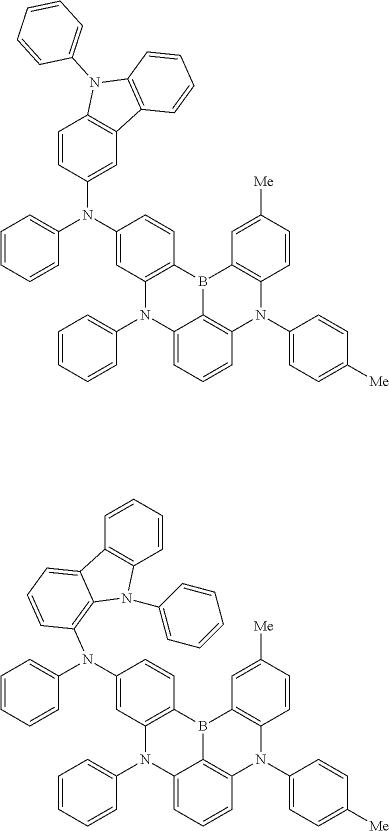 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1]

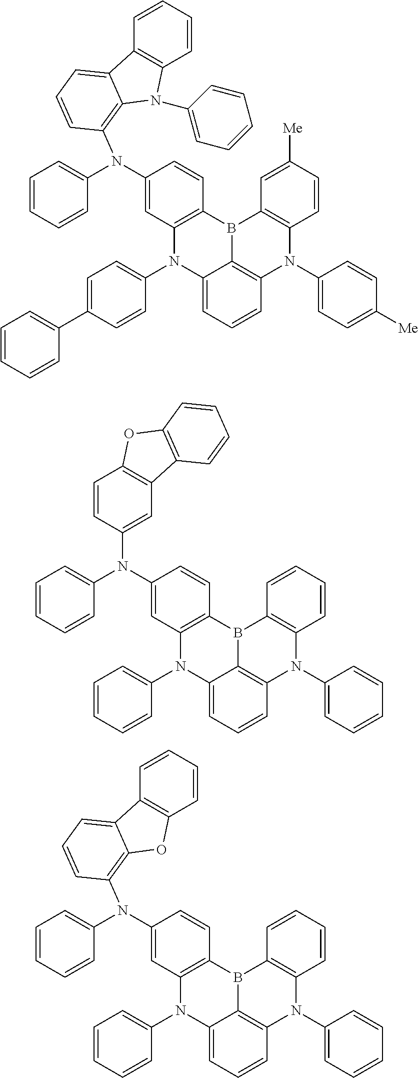

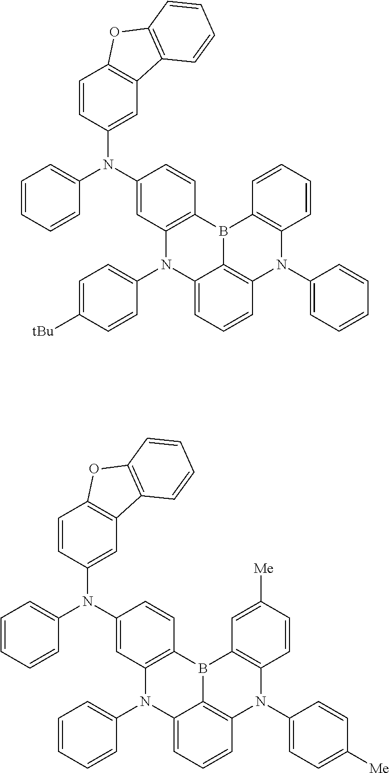 [SMILES: CC(C)(C)c1ccc(N2c3cc(N(c4ccccc4)c4ccc5oc6ccccc6c5c4)ccc3B3c4ccccc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccccc4)c4cccc2c43)cc1]

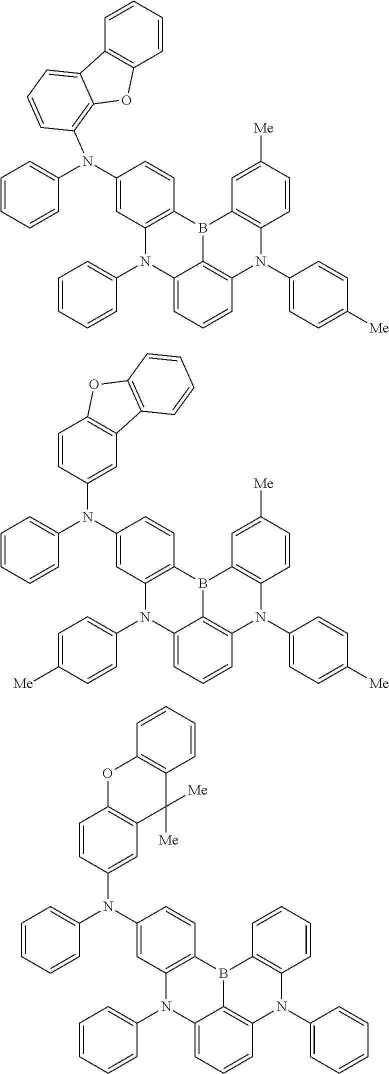

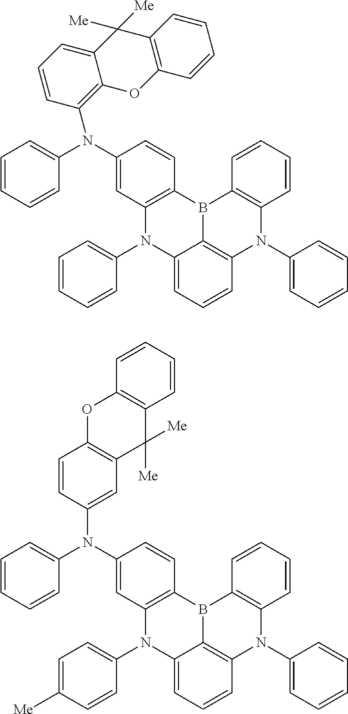 [SMILES: CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1]

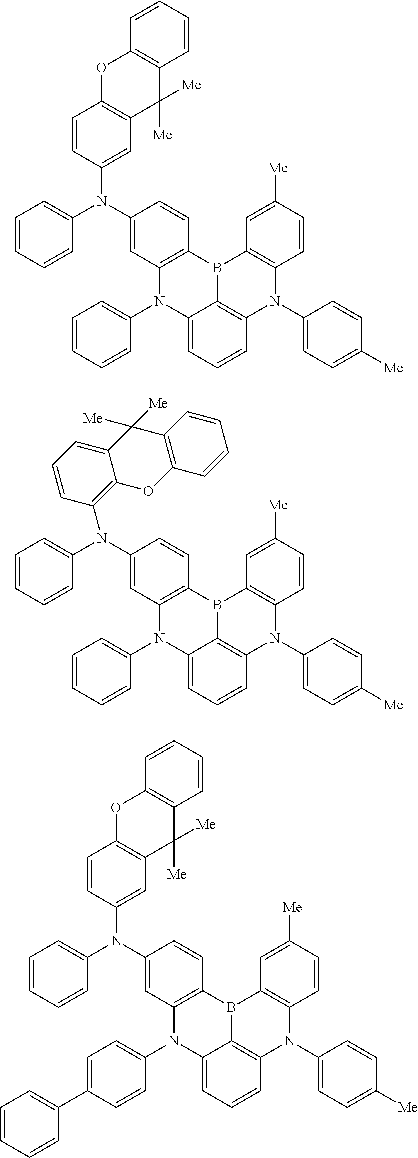 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

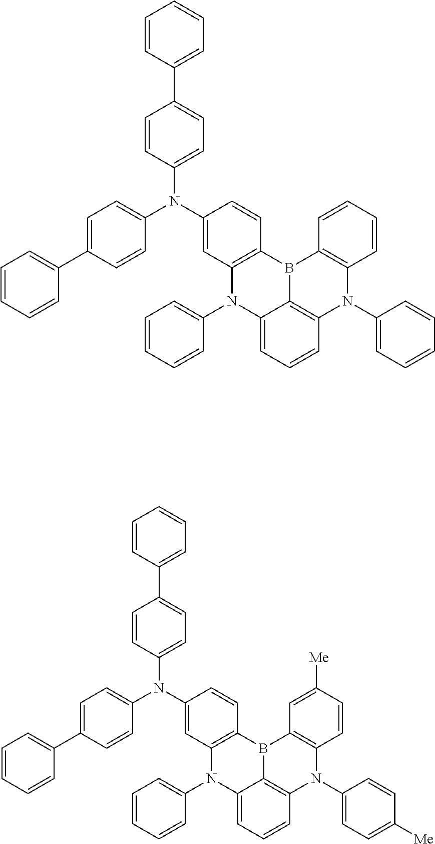 [SMILES: c1ccc(-c2ccc(N(c3ccc(-c4ccccc4)cc3)c3ccc4c(c3)N(c3ccccc3)c3cccc5c3B4c3ccccc3N5c3ccccc3)cc2)cc1 ; Cc1ccc(N2c3ccc(C)cc3B3c4ccc(N(c5ccc(-c6ccccc6)cc5)c5ccc(-c6ccccc6)cc5)cc4N(c4ccccc4)c4cccc2c43)cc1]

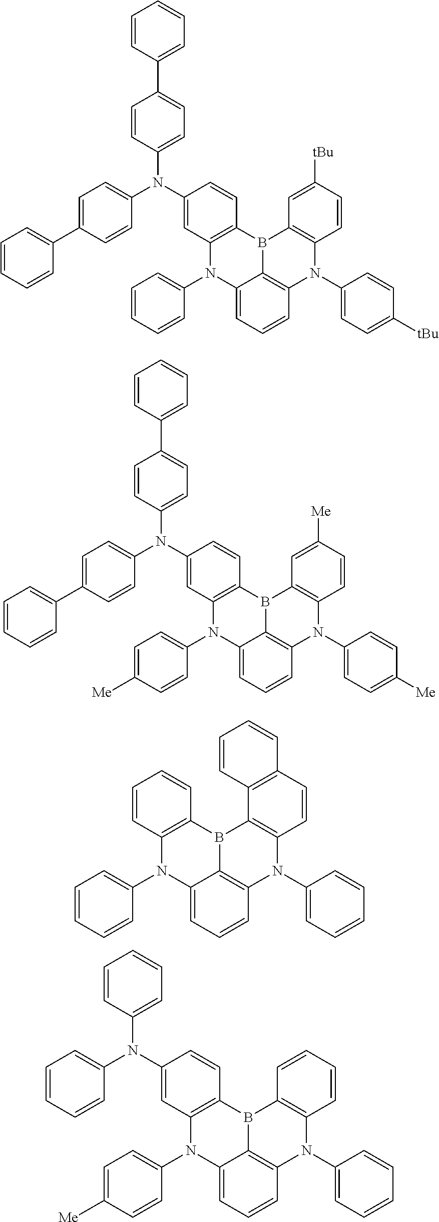

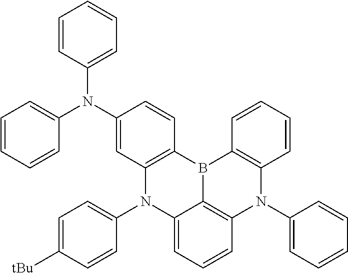 [SMILES: CC(C)(C)c1ccc(N2c3cc(N(c4ccccc4)c4ccccc4)ccc3B3c4ccccc4N(c4ccccc4)c4cccc2c43)cc1]

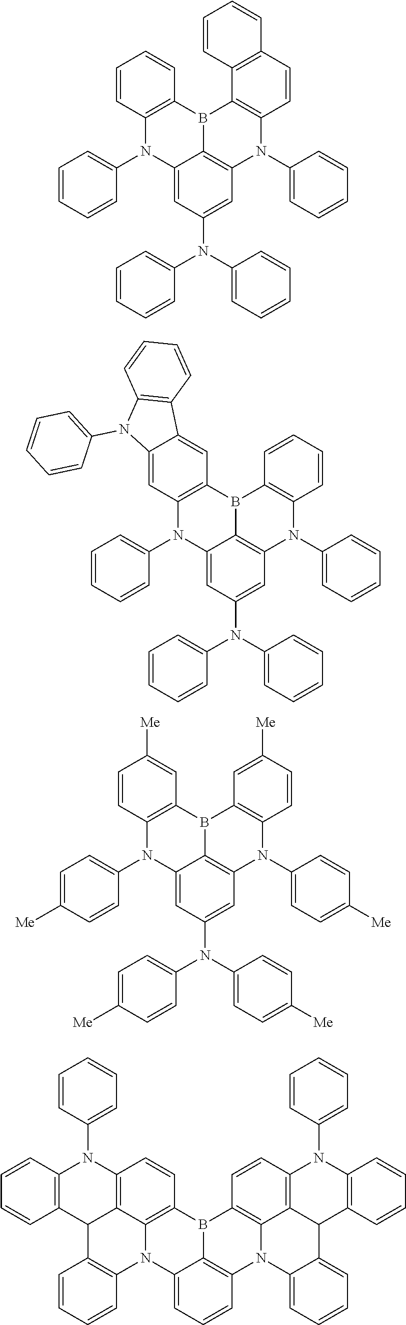

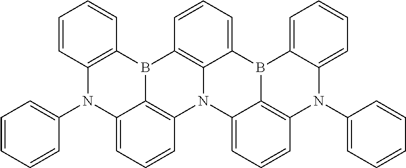 [SMILES: c1ccc(N2c3ccccc3B3c4cccc5c4N(c4cccc2c43)c2cccc3c2B5c2ccccc2N3c2ccccc2)cc1]

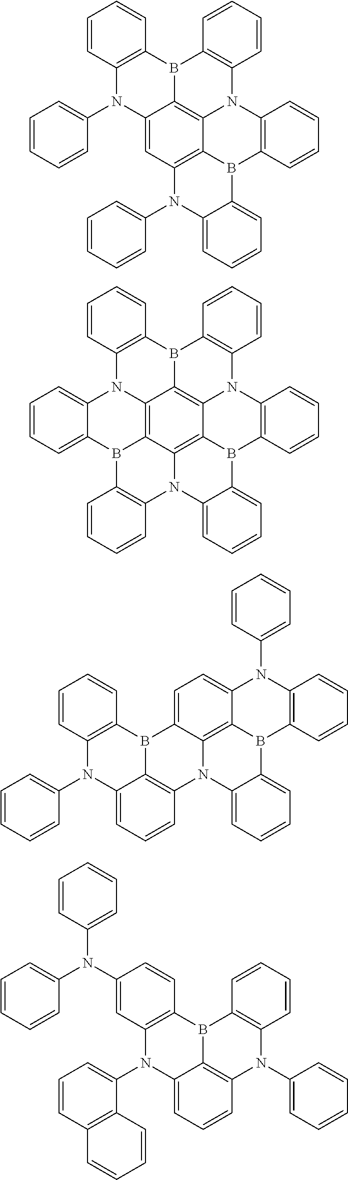

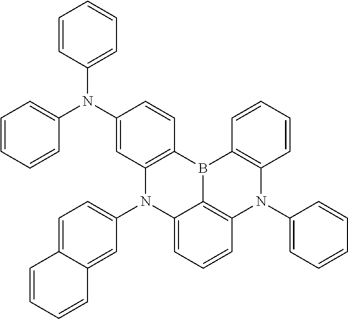 [SMILES: c1ccc(N(c2ccccc2)c2ccc3c(c2)N(c2ccc4ccccc4c2)c2cccc4c2B3c2ccccc2N4c2ccccc2)cc1]

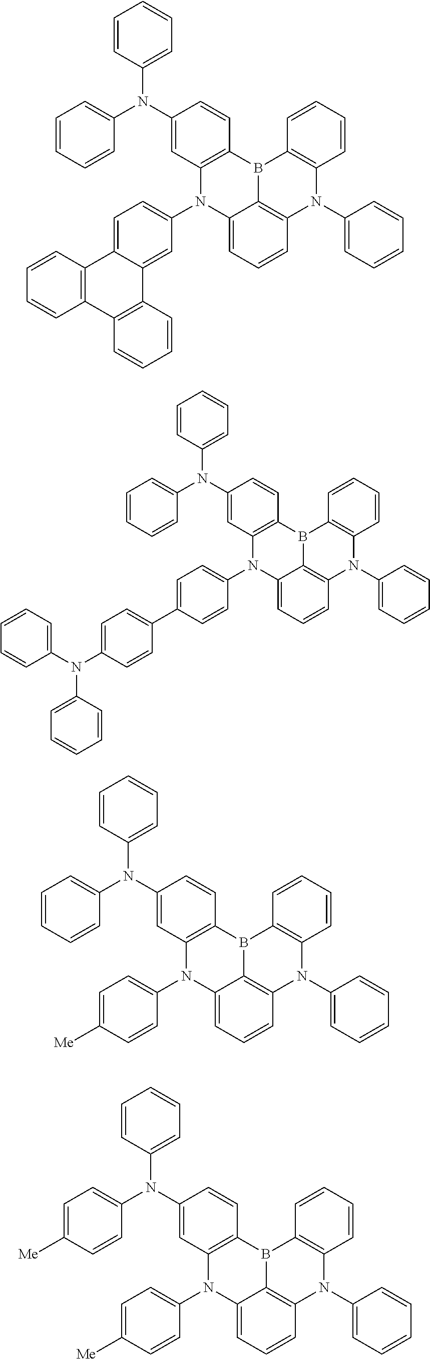

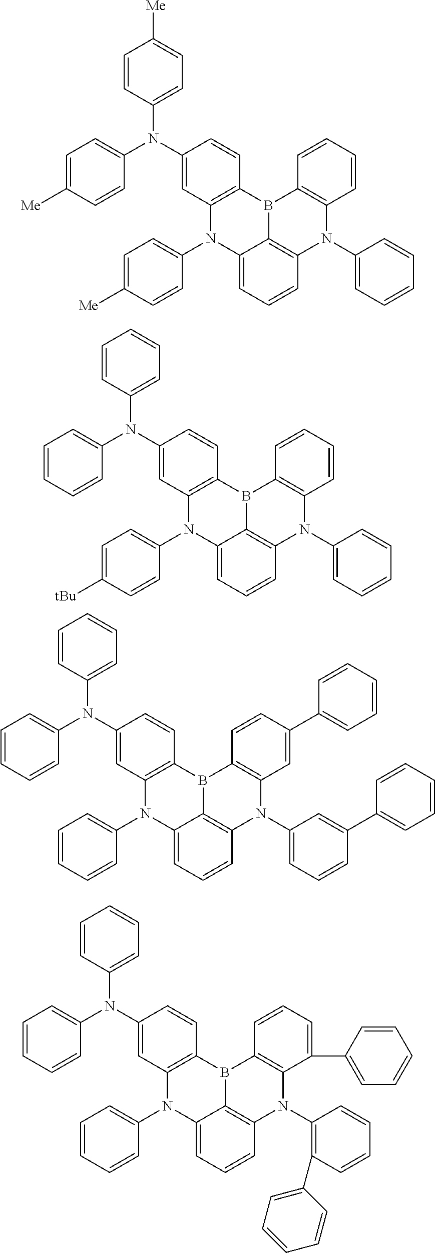

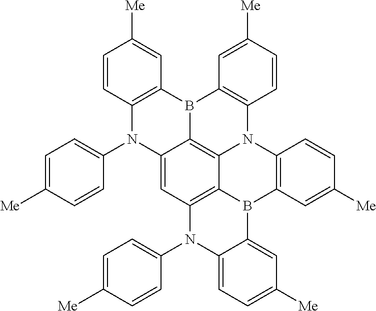 [SMILES: Cc1ccc(N2c3ccc(C)cc3B3c4cc(C)ccc4N4c5ccc(C)cc5B5c6cc(C)ccc6N(c6ccc(C)cc6)c6cc2c3c4c65)cc1]

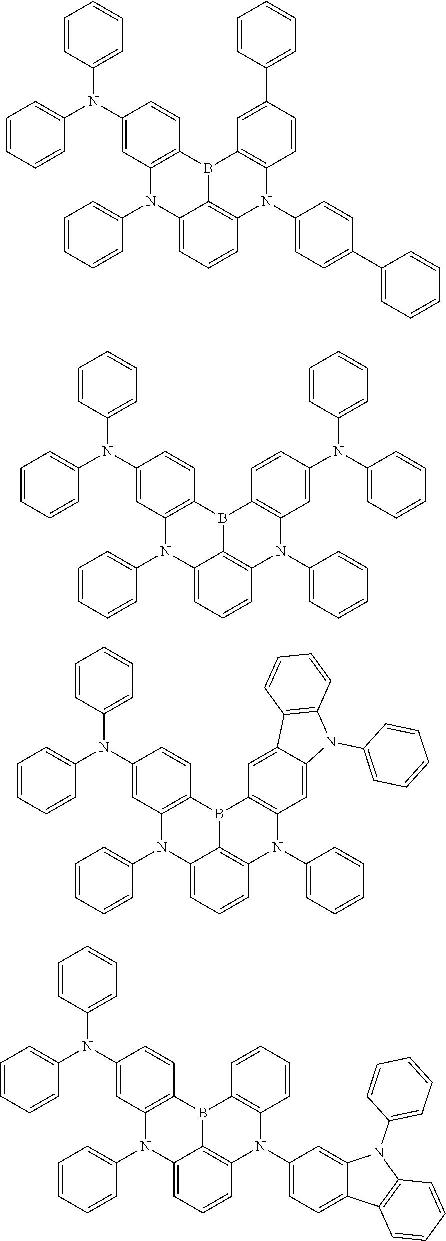

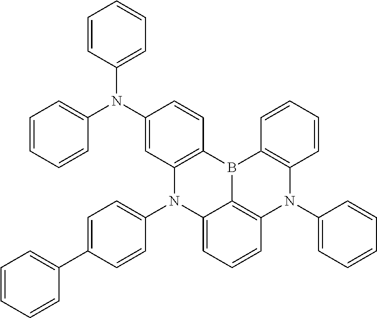 [SMILES: c1ccc(-c2ccc(N3c4cc(N(c5ccccc5)c5ccccc5)ccc4B4c5ccccc5N(c5ccccc5)c5cccc3c54)cc2)cc1]

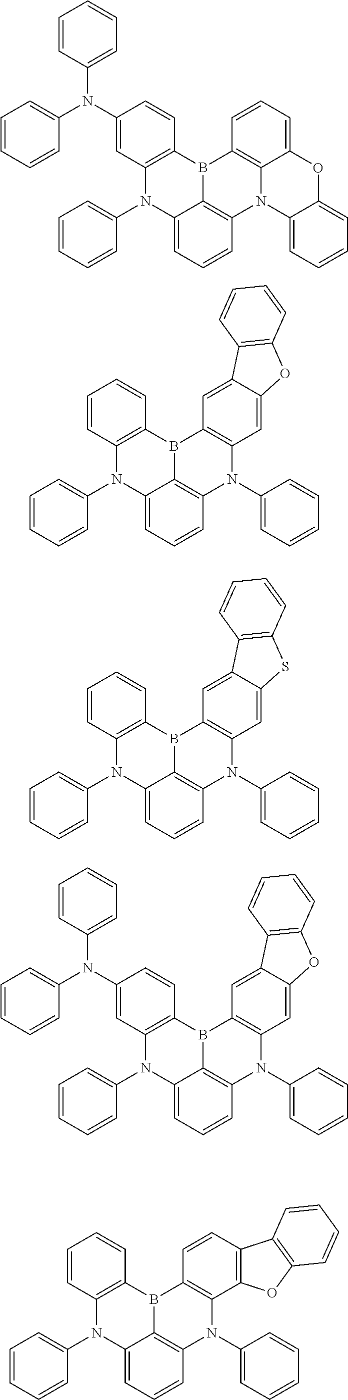

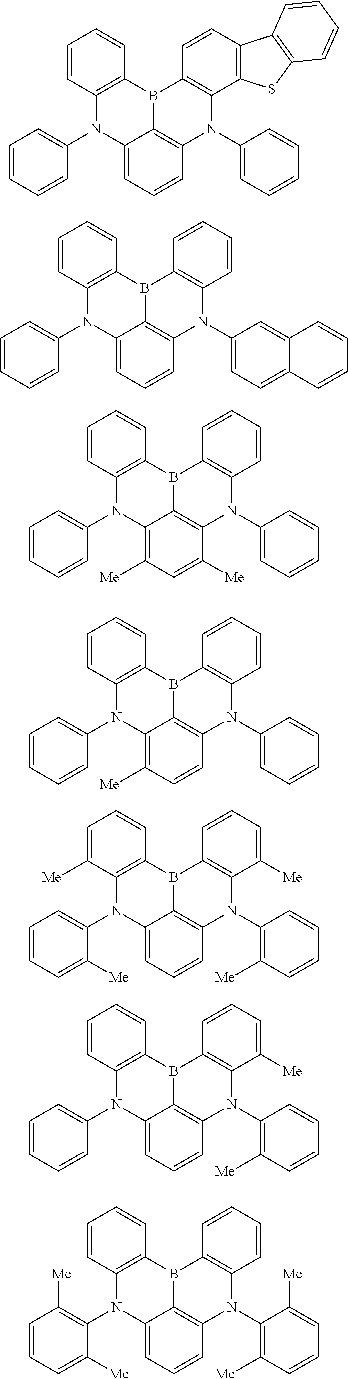

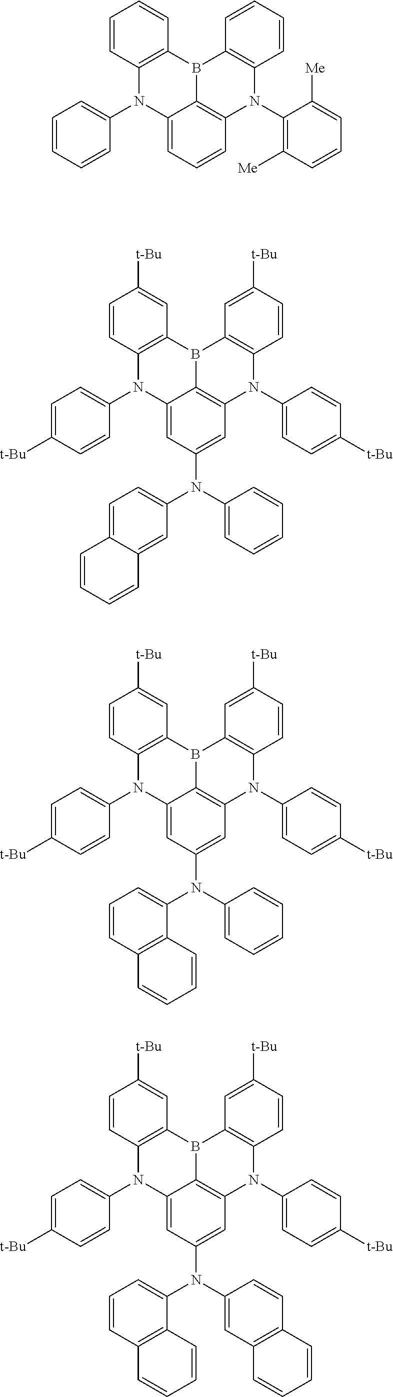 [SMILES: Cc1cccc(C)c1N1c2ccccc2B2c3ccccc3N(c3ccccc3)c3cccc1c32 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc6ccccc6c5)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6ccccc56)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccc6ccccc6c5)c5cccc6ccccc56)cc2c43)cc1]

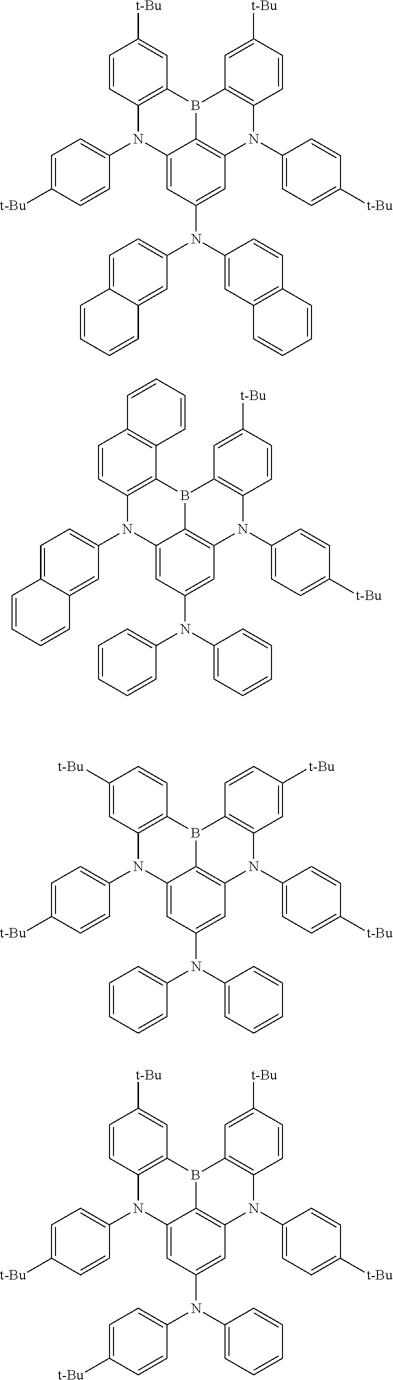

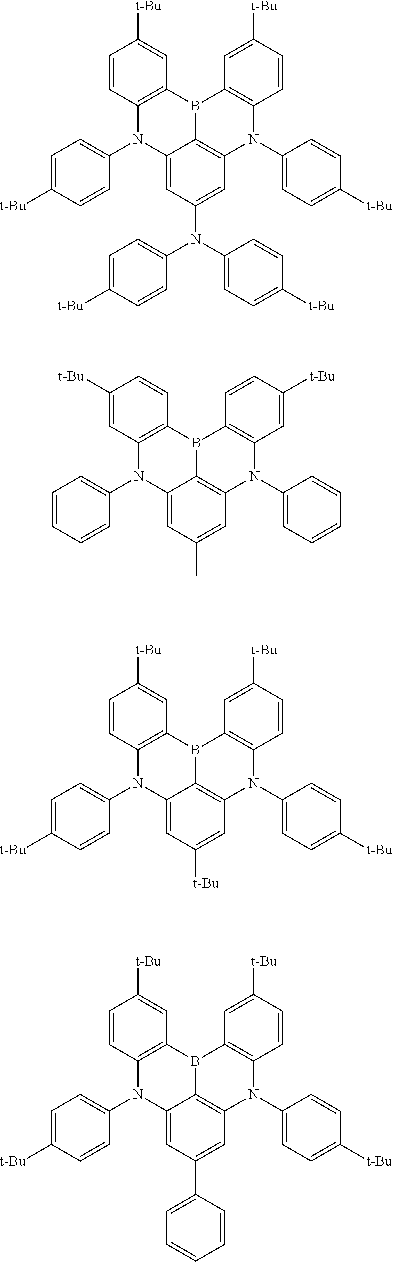 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1 ; Cc1cc2c3c(c1)N(c1ccccc1)c1cc(C(C)(C)C)ccc1B3c1ccc(C(C)(C)C)cc1N2c1ccccc1 ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5ccccc5)cc2c43)cc1]

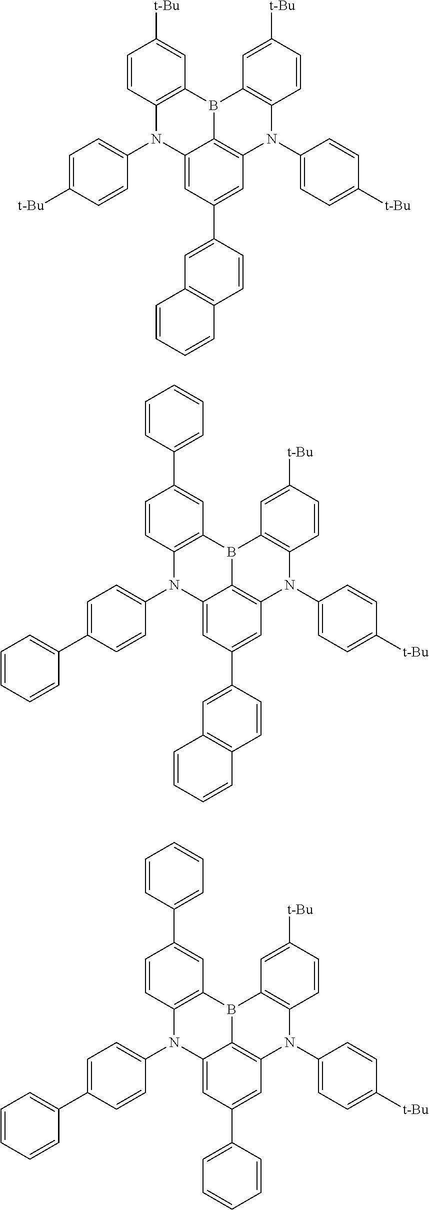

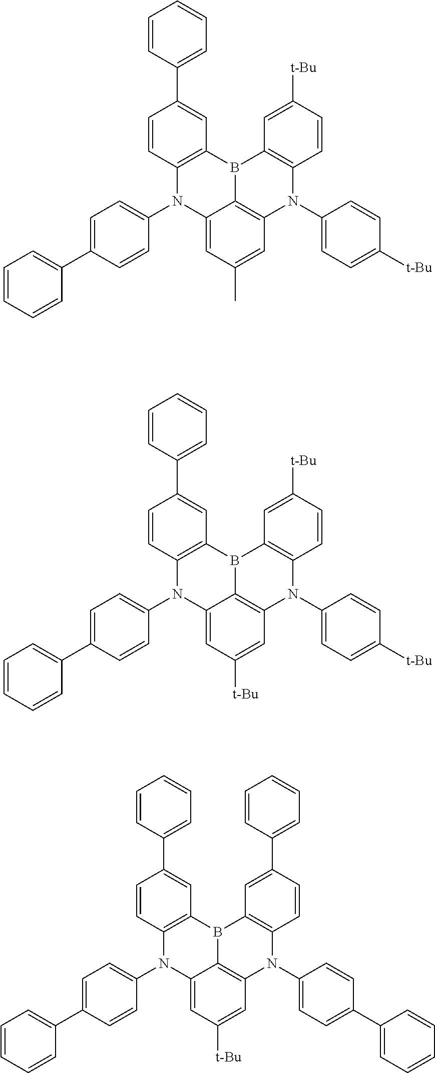 [SMILES: Cc1cc2c3c(c1)N(c1ccc(C(C)(C)C)cc1)c1ccc(C(C)(C)C)cc1B3c1cc(-c3ccccc3)ccc1N2c1ccc(-c2ccccc2)cc1 ; CC(C)(C)c1ccc(N2c3ccc(C(C)(C)C)cc3B3c4cc(-c5ccccc5)ccc4N(c4ccc(-c5ccccc5)cc4)c4cc(C(C)(C)C)cc2c43)cc1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

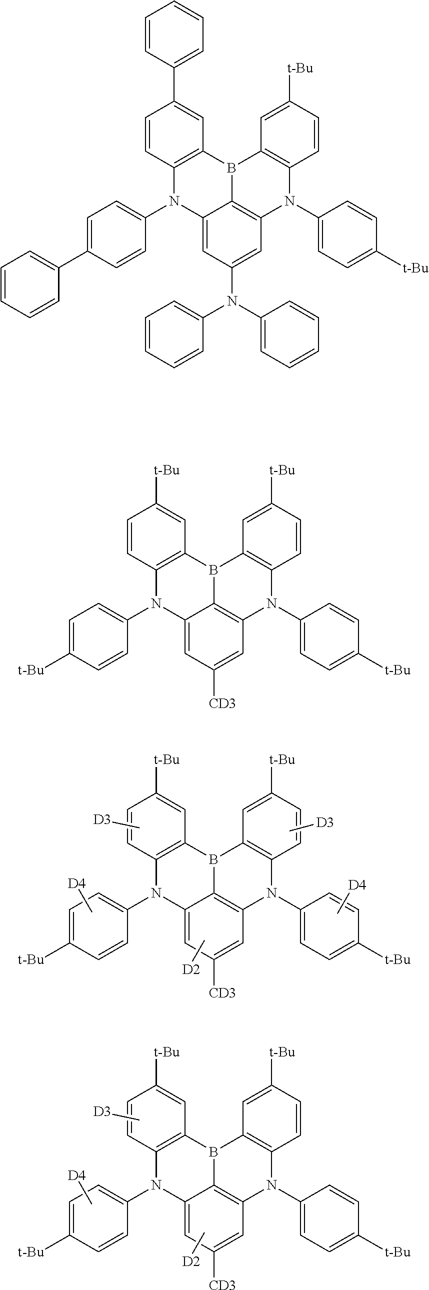

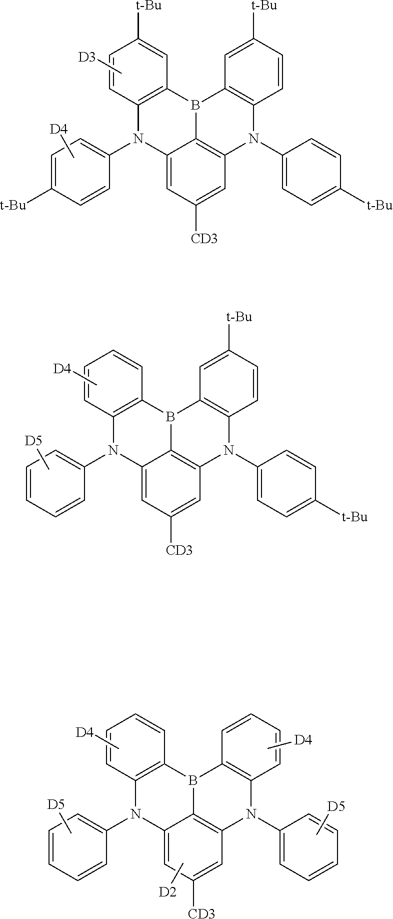

In the compounds, D2 to D5 each mean that 2 to 5 hydrogens are replaced with deuterium.

The organic electroluminescent device according to one embodiment comprises: a first electrode; a second electrode; and, as organic layers other than a plurality of light-emitting layers disposed between the first electrode and the second electrode, a hole transport layer, a hole auxiliary layer, an electron-blocking layer, and a light-emitting auxiliary layer. The organic electroluminescent device may further comprise one or more layers selected from a hole injection layer, an electron transport layer, an electron injection layer, an interlayer, a hole-blocking layer, and an electron buffer layer, in addition to the hole transport layer, the hole auxiliary layer, the electron-blocking layer, and the light-emitting auxiliary layer. The organic layers may further comprise, in addition to the light-emitting materials of the present disclosure, an amine-based compound and/or an azine-based compound. Specifically, the hole injection layer, the hole transport layer, the hole auxiliary layer, the light-emitting layer, the light-emitting auxiliary layer, or the electron-blocking layer may comprise an amine-based compound, for example, an arylamine-based compound, a styrylarylamine-based compound, or the like, as a hole injection material, a hole transport material, a hole auxiliary material, a light-emitting material, a light-emitting auxiliary material, or an electron-blocking material. In addition, the electron transport layer, the electron injection layer, the electron buffer layer, and the hole-blocking layer may comprise an azine-based compound as an electron transport material, an electron injection material, an electron buffer material, or a hole-blocking material. In addition, the organic layers may further comprise one or more metals selected from the group consisting of Group 1 metals, Group 2 metals, fourth-period transition metals, fifth-period transition metals, lanthanide series metals, and d-transition elements, or one or more complex compounds comprising such metals.

One of the first electrode and the second electrode may be an anode, and the other may be a cathode. In this case, each of the first electrode and the second electrode may be formed of a transparent conductive material, or may be formed of a semi-transmissive or reflective conductive material. Depending on the type of material forming the first electrode and the second electrode, the organic electroluminescent device may be of a top-emission type, a bottom-emission type, or a dual-emission type.

Between the anode and the plurality of light-emitting layers according to the present disclosure, a hole injection layer, a hole transport layer, an electron-blocking layer, or a combination thereof may be used. The hole injection layer may include a plurality of layers for the purpose of lowering a hole injection barrier (or a hole injection voltage) from the anode to the hole transport layer or the electron-blocking layer, and in each layer, two compounds may be used simultaneously. In addition, the hole injection layer may be doped with a p-dopant. The electron-blocking layer is positioned between the hole transport layer (or the hole injection layer) and the light-emitting layer, and may prevent overflow of electrons from the light-emitting layer, thereby confining excitons within the light-emitting layer and preventing emission leakage. The hole transport layer or the electron-blocking layer may include a plurality of layers, and a plurality of compounds may be used in each layer.

Between the plurality of light-emitting layers according to the present disclosure and the cathode, an electron buffer layer, a hole-blocking layer, an electron transport layer, an electron injection layer, or a combination thereof may be used. The electron buffer layer may include a plurality of layers for the purpose of controlling electron injection and improving interfacial characteristics between the light-emitting layer and the electron injection layer, and in each layer, two compounds may be used simultaneously. The hole-blocking layer is positioned between the electron transport layer (or the electron injection layer) and the light-emitting layer, and serves to block holes from reaching the cathode, thereby improving a recombination probability of electrons and holes in the light-emitting layer. The hole-blocking layer or the electron transport layer may also include a plurality of layers, and a plurality of compounds may be used in each layer. In addition, the electron injection layer may be doped with an n-dopant.

The light-emitting auxiliary layer is a layer positioned between the anode and the light-emitting layer or between the cathode and the light-emitting layer. When the light-emitting auxiliary layer is positioned between the anode and the light-emitting layer, it may be used to facilitate injection and/or transport of holes or to block overflow of electrons, and when the light-emitting auxiliary layer is positioned between the cathode and the light-emitting layer, it may be used to facilitate injection and/or transport of electrons or to block overflow of holes. In addition, the hole auxiliary layer is positioned between the hole transport layer (or the hole injection layer) and the light-emitting layer, and may exhibit an effect of facilitating or blocking a transport speed (or an injection speed) of holes, thereby adjusting charge balance. When the organic electroluminescent device includes two or more hole transport layers, an additionally included hole transport layer may be used as a hole auxiliary layer or an electron-blocking layer. The light-emitting auxiliary layer, the hole auxiliary layer, or the electron-blocking layer may have an effect of improving efficiency and/or lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiOₓ (1≤x≤2), AlOₓ (1≤x≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, it is also preferable to dispose, on at least one surface of a pair of electrodes, a mixed region of an electron transport compound and a reductive dopant, or a mixed region of a hole transport compound and an oxidative dopant. By such a configuration, the electron transport compound is reduced to an anion, thereby facilitating injection and transport of electrons from the mixed region to a light-emitting medium. In addition, since the hole transport compound is oxidized to become a cation, injection and transport of holes from the mixed region to the light-emitting medium are facilitated. Examples of preferable oxidative dopants include various Lewis acids and acceptor compounds, and examples of preferable reductive dopants include alkali metals, alkali metal compounds, alkaline earth metals, rare earth metals, and mixtures thereof. In addition, by using a reductive dopant layer as a charge generation layer, an organic electroluminescent device having two or more light-emitting layers and exhibiting white emission can be manufactured.

An organic electroluminescent device according to another embodiment comprises: a first electrode; a second electrode facing the first electrode; and two or more light-emitting units disposed between the first electrode and the second electrode and comprising at least one light-emitting layer, wherein at least one of the light-emitting units sequentially comprises a first light-emitting layer, a second light-emitting layer, and a third light-emitting layer which are adjacent to one another.

The organic electroluminescent device according to one embodiment of the present disclosure is an organic electroluminescent device having a tandem structure, and in such a tandem organic electroluminescent device, a single light-emitting unit (light-emitting unit) may be formed in a structure in which two or more light-emitting units are connected by a charge generation layer. The organic electroluminescent device may comprise two or more light-emitting units, for example, three or more light-emitting units, which are stacked between a first electrode and a second electrode facing each other on a substrate and include light-emitting layers that emit light in a specific wavelength region. According to one embodiment, the organic electroluminescent device may include a plurality of light-emitting units, and each of the light-emitting units may include a hole transport band, a light-emitting layer, and an electron transport band, and the hole transport band may include a hole injection layer and a hole transport layer, and the electron transfer zone may include an electron transport layer and an electron injection layer. According to one embodiment, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. It may include one or more charge generation layers located between each light-emitting unit. The charge generation layer refers to the layer in which holes and electrons are generated when voltage is applied. When there are three or more light-emitting units, a charge generation layer may be located between each light-emitting unit. At this time, the plurality of charge generation layers may be the same or different from each other. By disposing the charge generation layer between light-emitting units, current efficiency is increased in each light-emitting unit and charges can be smoothly distributed. Specifically, the charge generation layer is provided between two adjacent stacks and can serve to drive a tandem organic electroluminescent device using only a pair of anodes and cathodes without a separate internal electrode located between the stacks.

The charge generation layer may be composed of an n-type charge generation layer and a p-type charge generation layer. The n-type charge generation layer may be doped with an alkali metal, an alkaline earth metal, or a compound of an alkali metal and an alkaline earth metal. The alkali metal may comprise one selected from the group consisting of Li, Na, K, Rb, Cs, Fr, Yb, and combinations thereof, and the alkaline earth metal may comprise one selected from the group consisting of Be, Mg, Ca, Sr, Ba, Ra, and combinations thereof. The p-type charge generation layer may be composed of a metal or an organic material doped with a p-type dopant. For example, the metal may be composed of one metal selected from the group consisting of Al, Cu, Fe, Pb, Zn, Au, Pt, W, In, Mo, Ni, and Ti, or an alloy of two or more thereof. In addition, as the p-type dopant and host material used in the p-type-doped organic material, materials commonly used in the art may be employed.

Formation of each layer of the organic electroluminescent device of the present disclosure may be carried out by any one method selected from dry film-forming methods such as vacuum deposition, sputtering, plasma, and ion plating, or wet film-forming methods such as spin coating, dip coating, and flow coating. In the case of the wet film-forming method, a thin film is formed by dissolving or dispersing materials for forming each layer in an appropriate solvent such as ethanol, chloroform, tetrahydrofuran, or dioxane, and any solvent may be used as long as the materials for forming each layer can be dissolved or dispersed therein and there is no problem in film-forming properties.

When forming a film of the organic electroluminescent compound according to one embodiment, the film may be formed by the methods listed above, and is commonly formed by a co-deposition process or a mixed deposition process. The co-deposition refers to a method in which two or more materials are placed in respective separate crucible sources, currents are applied to the respective cells simultaneously to evaporate the materials, and the materials are deposited in a mixed manner. The mixed deposition refers to a method in which two or more materials are mixed in one crucible source prior to deposition, and a current is applied to a single cell to evaporate the materials, thereby depositing the materials in a mixed manner.

According to one embodiment, the present disclosure can provide a display device having high current efficiency and superior lifespan characteristics. In addition, by using the organic electroluminescent device of the present disclosure, it is possible to manufacture a display device, for example, a smartphone, a tablet, a notebook, a PC, a TV, or an in-vehicle display device, or a lighting device, for example, an outdoor or indoor lighting device.

Hereinafter, for a detailed understanding of the present disclosure, a method for manufacturing the organic electroluminescent device according to the present disclosure and characteristics thereof will be described.

### [Device Examples 1 to 11] Manufacture of Organic Electroluminescent Device Including a Plurality of Light-Emitting Layers Deposited with the Compounds According to the Present Disclosure

OLEDs according to the present disclosure were manufactured. First, a transparent ITO thin-film electrode on a glass substrate for OLEDs (manufactured by Geomatec) was ultrasonically cleaned using acetone and isopropyl alcohol sequentially, and then stored in isopropyl alcohol before use. Next, the ITO substrate was mounted on a substrate holder of a vacuum deposition apparatus. Compound HI-1 was placed in one cell of the vacuum deposition apparatus, and Compound HT-1 was placed in another cell. The two materials were evaporated at different rates to dope Compound HI-1 in an amount of 5 wt % based on a total amount of Compound HI-1 and Compound HT-1, thereby depositing a hole injection layer having a thickness of 10 nm. Subsequently, Compound HT-1 was deposited on the hole injection layer to form a first hole transport layer having a thickness of 80 nm. Thereafter, Compound HT-2 was placed in another cell of the vacuum deposition apparatus and evaporated by applying a current to the cell, thereby depositing a second hole transport layer having a thickness of 15 nm on the first hole transport layer. After formation of the hole injection layer and the hole transport layers, a first light-emitting layer was deposited thereon as follows. A compound shown in Table 1 below was placed in a cell as a host, and Compound D-1 was placed in another cell as a dopant. The two materials were evaporated at different rates to dope the dopant in an amount of 2 wt % based on a total amount of the host and the dopant, thereby depositing a first light-emitting layer having a thickness of 5 nm on the second hole transport layer. Next, a second light-emitting layer was deposited on the first light-emitting layer as follows. A plurality of compounds shown in Table 1 below were placed in a cell of the vacuum deposition apparatus as hosts, and Compound D-1 was placed in another cell as a dopant. The hosts were deposited at a weight ratio of 1:1, and the dopant was doped in an amount of 2 wt %, thereby depositing a second light-emitting layer having a thickness of 8 nm. Thereafter, a third light-emitting layer was deposited on the second light-emitting layer as follows. A compound shown in Table 1 below was placed in a cell of the vacuum deposition apparatus as a host, and Compound D-1 was placed in another cell as a dopant. The two materials were evaporated at different rates to dope the dopant in an amount of 2 wt % based on a total amount of the host and the dopant, thereby depositing a third light-emitting layer having a thickness of 5 nm. After deposition of the light-emitting layers, Compound ET-1 was deposited as a hole-blocking layer material to a thickness of 5 nm. Subsequently, as electron transport layer materials, Compound ET-2 and Compound EI-1 were respectively placed in two cells of the vacuum deposition apparatus, and the two materials were deposited at a weight ratio of 2:1 to a thickness of 25 nm. Thereafter, Yb and LiF were deposited as an electron injection layer at a weight ratio of 2:1 to a thickness of 1 nm on the electron transport layer, and then an Al cathode was deposited to a thickness of 80 nm on the electron injection layer using another vacuum deposition apparatus, thereby manufacturing an OLED. Each compound was purified by vacuum sublimation under 10⁻⁶ Torr before use.

### [Device Comparative Example 1] Manufacture of Organic Electroluminescent Device Including a Single Light-Emitting Layer

An OLED was manufactured in the same manner as in Device Example 1, except that a single light-emitting layer having a thickness of 18 nm was deposited by introducing a plurality of compounds shown in Table 1 below as hosts and introducing Compound D-1 as a dopant, depositing the hosts at a weight ratio of 1:1, and doping the dopant in an amount of 2 wt %.

A current efficiency at a luminance of 1,000 nit and a time required for the light intensity to decrease from 100% to 95% at a luminance of 1,280 nit (lifespan: T₉₅) of the organic electroluminescent devices according to Device Examples 1 to 11 and Device Comparative Example 1 manufactured as described above were respectively measured, and the results are shown in Table 1 below.

TABLE 1

| | First Light- | Second Light- | Third Light- | Current | |
|---|---|---|---|---|---|
| | Emitting | Emitting | Emitting | Efficiency | Lifespan |
| | Layer | Layer | Layer | [cd/A] | [%] |
| Device | H1-1 | H2-1:H2-2 | H3-1 | 6.1 | 112 |
| Example1 | | | | | |
| Device | H1-1 | H2-1:H2-2 | H3-2 | 5.9 | 156 |
| Example 2 | | | | | |
| Device | H1-1 | H2-1:H2-2 | H3-3 | 5.8 | 167 |
| Example 3 | | | | | |
| Device | H1-1 | H2-1:H2-2 | H3-4 | 5.7 | 174 |
| Example 4 | | | | | |
| Device | H1-1 | H2-1:H2-2 | H3-5 | 5.8 | 130 |
| Example 5 | | | | | |
| Device | H1-1 | H2-1:H2-2 | H3-6 | 5.8 | 170 |
| Example 6 | | | | | |
| Device | H1-1 | H2-1:H2-2 | H3-7 | 6.0 | 228 |
| Example 7 | | | | | |
| Device | H1-1 | H2-1:H2-2 | H3-8 | 6.2 | 31 |
| Example 8 | | | | | |
| Device | H1-1 | H2-1:H2-2 | H3-9 | 5.6 | 125 |
| Example 9 | | | | | |
| Device | H1-1 | H2-1:H2-2 | H3-10 | 5.9 | 140 |
| Example 10 | | | | | |
| Device | H1-1 | H2-1:H2-2 | H3-11 | 6.2 | 95 |
| Example 11 | | | | | |
| Device | — | H2-1:H2-2 | — | 5.6 | 95 |
| Comparative | | | | | |
| Example 1 | | | | | |

As shown in Table 1, it can be confirmed that the organic electroluminescent device including a plurality of light-emitting layers according to the present disclosure has higher current efficiency and superior lifespan characteristics as compared with an organic electroluminescent device including only a single light-emitting layer.

The compounds used in Device Examples 1 to 11 and Device Comparative Example 1 are specifically shown in Table 2 below.

TABLE 2

| | |
|---|---|
| Hole Injection Layer/Hole Transport Layer | 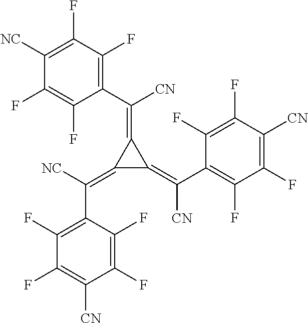 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| | HI-1 |
| | 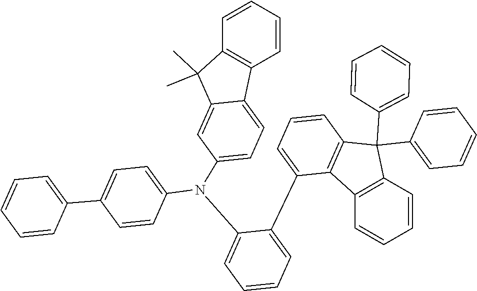 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21] |
| | HT-1 |
| | 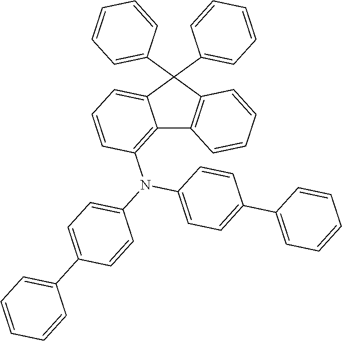 [SMILES: c1ccc(-c2ccc(N(c3ccc(-c4ccccc4)cc3)c3cccc4c3-c3ccccc3C4(c3ccccc3)c3ccccc3)cc2)cc1] |
| | HT-2 |
| First Light- Emitting Layer | 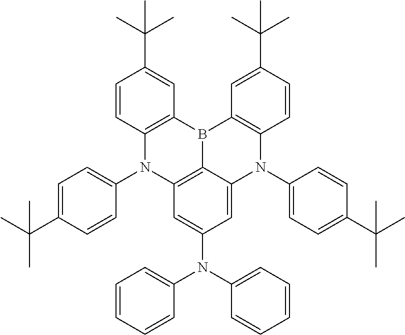 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | D-1 |
| | 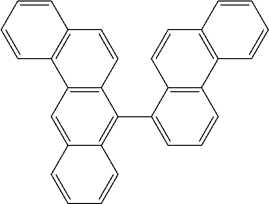 [SMILES: c1ccc2c(-c3cccc4c3ccc3ccccc34)c3ccc4ccccc4c3cc2c1] |
| | H1-1 |
| Second Light- Emitting Layer | 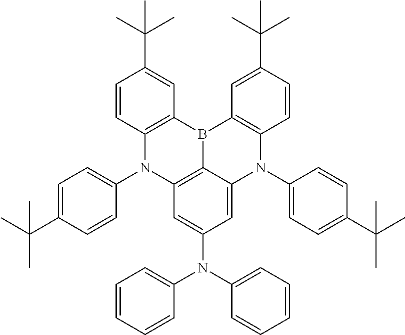 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | D-1 |
| | 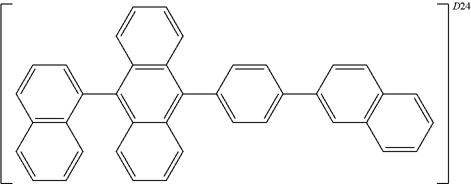 |
| | H2-1 |
| | 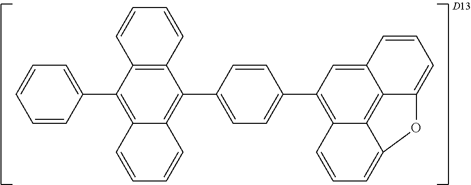 |
| | H2-2 |
| Third Light- Emitting Layer | 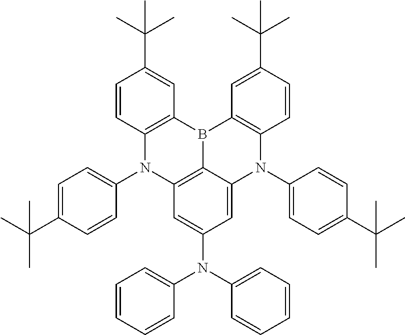 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | D-1 |
| | 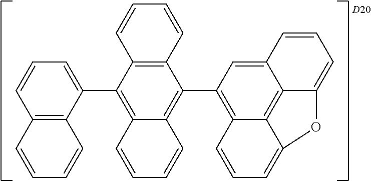 |
| | H3-1 |
| | 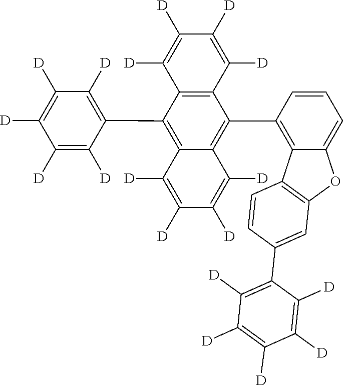 [SMILES: [2H]c1c([2H])c([2H])c(-c2ccc3c(c2)oc2cccc(-c4c5c([2H])c([2H])c([2H])c([2H])c5c(-c5c([2H])c([2H])c([2H])c([2H])c5[2H])c5c([2H])c([2H])c([2H])c([2H])c45)c23)c([2H])c1[2H]] |
| | H3-2 |
| | 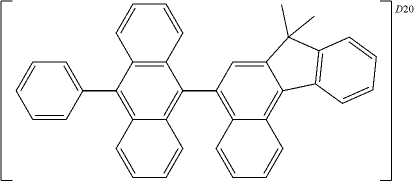 |
| | H3-3 |
| | 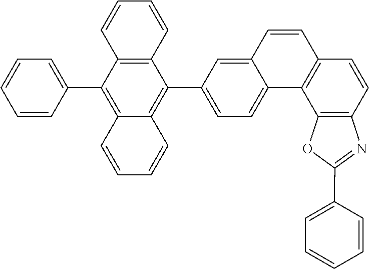 [SMILES: c1ccc(-c2nc3ccc4ccc5cc(-c6c7ccccc7c(-c7ccccc7)c7ccccc67)ccc5c4c3o2)cc1] |
| | H3-4 |
| | 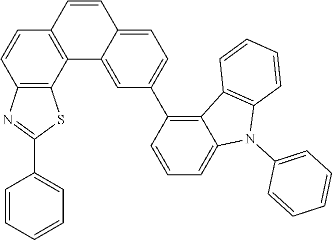 [SMILES: c1ccc(-c2nc3ccc4ccc5ccc(-c6cccc7c6c6ccccc6n7-c6ccccc6)cc5c4c3s2)cc1] |
| | H3-5 |
| | 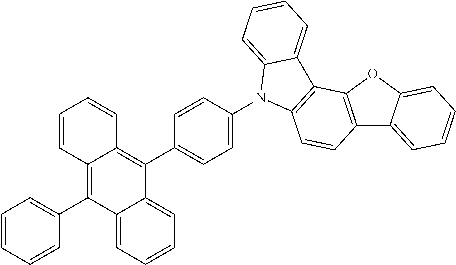 [SMILES: c1ccc(-c2c3ccccc3c(-c3ccc(-n4c5ccccc5c5c6oc7ccccc7c6ccc54)cc3)c3ccccc23)cc1] |
| | H3-6 |
| | 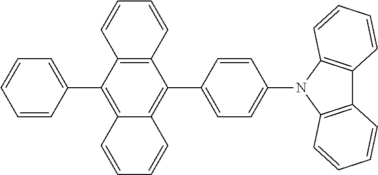 [SMILES: c1ccc(-c2c3ccccc3c(-c3ccc(-n4c5ccccc5c5ccccc54)cc3)c3ccccc23)cc1] |
| | H3-7 |
| | 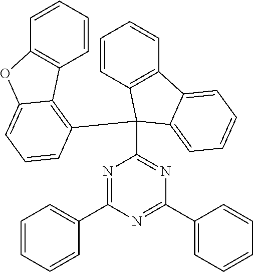 [SMILES: c1ccc(-c2nc(-c3ccccc3)nc(C3(c4cccc5oc6ccccc6c45)c4ccccc4-c4ccccc43)n2)cc1] |
| | H3-8 |
| | 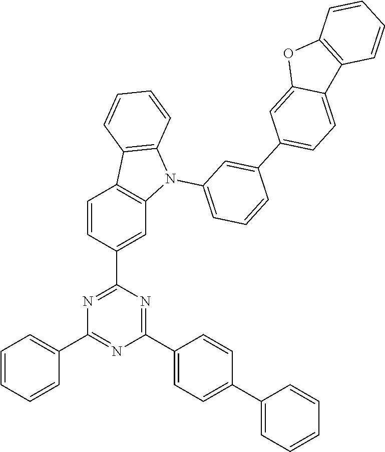 [SMILES: c1ccc(-c2ccc(-c3nc(-c4ccccc4)nc(-c4ccc5c6ccccc6n(-c6cccc(-c7ccc8c(c7)oc7ccccc78)c6)c5c4)n3)cc2)cc1] |
| | H3-9 |
| | 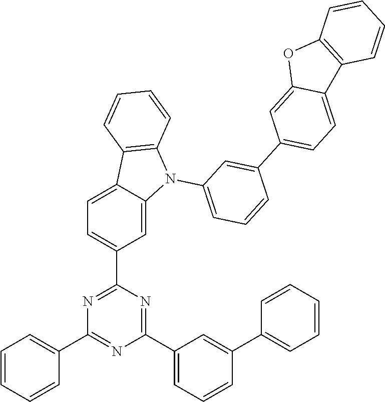 [SMILES: c1ccc(-c2cccc(-c3nc(-c4ccccc4)nc(-c4ccc5c6ccccc6n(-c6cccc(-c7ccc8c(c7)oc7ccccc78)c6)c5c4)n3)c2)cc1] |
| | H3-10 |
| | 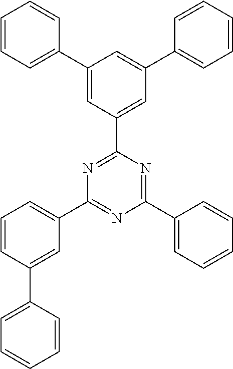 [SMILES: c1ccc(-c2cccc(-c3nc(-c4ccccc4)nc(-c4cc(-c5ccccc5)cc(-c5ccccc5)c4)n3)c2)cc1] |
| | H3-11 |
| Hole-Blocking Layer/ Electron Transport Layer/ Electron Injection Layer | 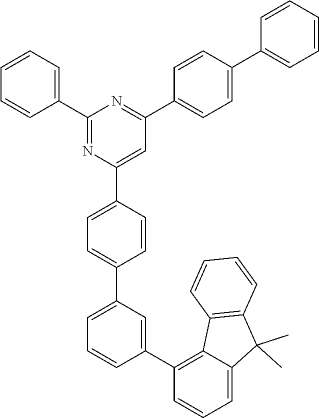 [SMILES: CC1(C)c2ccccc2-c2c(-c3cccc(-c4ccc(-c5cc(-c6ccc(-c7ccccc7)cc6)nc(-c6ccccc6)n5)cc4)c3)cccc21] |
| | ET-1 |
| | 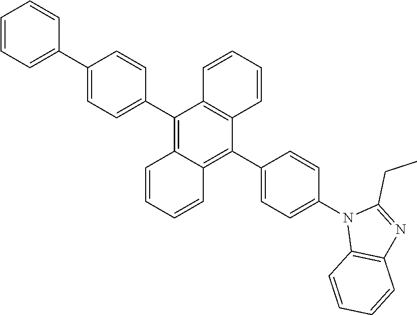 [SMILES: CCc1nc2ccccc2n1-c1ccc(-c2c3ccccc3c(-c3ccc(-c4ccccc4)cc3)c3ccccc23)cc1] |
| | ET-2 |
| | 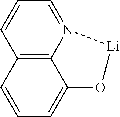 |
| | EI-1 |

1. An organic electroluminescent device comprising:
a first electrode;
a second electrode facing the first electrode; and
a first light-emitting layer, a second light-emitting layer, and a third light-emitting layer sequentially disposed between the first electrode and the second electrode and adjacent to one another,
wherein the first light-emitting layer is positioned closer to the first electrode and the third light-emitting layer is positioned closer to the second electrode,
wherein each of the first light-emitting layer, the second light-emitting layer, and the third light-emitting layer comprises at least one host compound and at least one dopant compound, and
wherein at least one pair of adjacent light-emitting layers comprises different host compounds.

2. The organic electroluminescent device according to claim 1, wherein the first light-emitting layer, the second light-emitting layer, and the third light-emitting layer comprise different host compounds from each other.

3. The organic electroluminescent device according to claim 1, wherein the first light-emitting layer and the third light-emitting layer comprise the same host compound.

4. The organic electroluminescent device according to claim 1, wherein the second light-emitting layer comprises an anthracene compound substituted or unsubstituted with deuterium, as a host compound.

5. The organic electroluminescent device according to claim 1, wherein the first light-emitting layer comprises a compound in which at least four rings are fused, as a host compound.

6. The organic electroluminescent device according to claim 1, wherein at least one layer among the first light-emitting layer, the second light-emitting layer, and the third light-emitting layer comprises a plurality of host materials.

7. The organic electroluminescent device according to claim 6, wherein at least two layers among the first light-emitting layer, the second light-emitting layer, and the third light-emitting layer comprise a plurality of host materials, wherein the plurality of host materials comprised in each layer are the same compounds, but content ratios thereof are different from each other.

8. The organic electroluminescent device according to claim 1, wherein a triplet energy of a host compound comprised in the third light-emitting layer is greater than a triplet energy of a host compound comprised in the second light-emitting layer.

9. The organic electroluminescent device according to claim 8, wherein the third light-emitting layer does not comprise a compound having an anthracene skeleton.

10. The organic electroluminescent device according to claim 1, wherein the first light-emitting layer, the second light-emitting layer, and the third light-emitting layer are blue light-emitting layers.

11. The organic electroluminescent device according to claim 1, wherein at least one layer among the first light-emitting layer, the second light-emitting layer, and the third light-emitting layer comprises a compound comprising a boron (B) atom substituted or unsubstituted with deuterium, as a dopant compound.

12. An organic electroluminescent device comprising:
a first electrode;
a second electrode facing the first electrode; and
two or more light-emitting units disposed between the first electrode and the second electrode and comprising at least one light-emitting layer,
wherein at least one of the light-emitting units sequentially comprises the first light-emitting layer, the second light-emitting layer, and the third light-emitting layer adjacent to one another according to claim 1.

13. The organic electroluminescent device according to claim 1, wherein the first light-emitting layer comprises a compound represented by the following Formula 1-1: 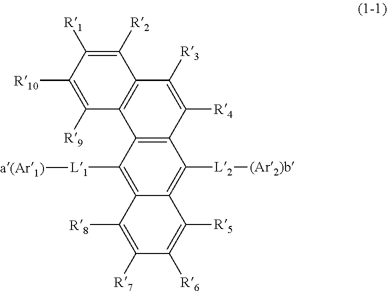
wherein,
L′₁ and L′₂ each independently represent a single bond, a substituted or unsubstituted (C₆-C₃₀)arylene, or a substituted or unsubstituted (3- to 30-membered)heteroarylene;
Ar′₁ and Ar′₂ each independently represent a substituted or unsubstituted (C₆-C₃₀)aryl or a substituted or unsubstituted (3- to 30-membered)heteroaryl; provided that at least one of Ar′₁ and Ar′₂ comprise the following Formula A: 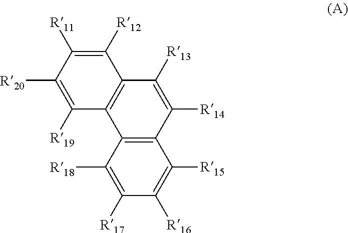
R′₁ to R′₂₀ each independently represent hydrogen, deuterium, halogen, cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)alkenylcycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino; and
a′ and b′ each independently represent an integer of 1 or 2, and when a′ and b′ are 2, each of Ar′₁ and Ar′₂ may be the same or different.

14. The organic electroluminescent device according to claim 1, wherein the second light-emitting layer comprises a compound represented by the following Formula 2-1: 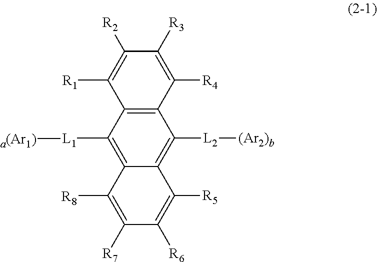
wherein,
L₁ and L₂ each independently represent a single bond, a substituted or unsubstituted (C₆-C₃₀)arylene, or a substituted or unsubstituted (3- to 30-membered)heteroarylene;
Ar₁ and Ar₂ each independently represent a substituted or unsubstituted (C₆-C₃₀)aryl or a substituted or unsubstituted (3- to 30-membered)heteroaryl;
R₁ to R₈ each independently represent hydrogen, deuterium, halogen, cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)alkenylcycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino; and
a and b each independently represent an integer of 1 or 2, and when a and b are 2, each of Ar₁ and Ar₂ may be the same or different.

15. The organic electroluminescent device according to claim 1, wherein the third light-emitting layer comprises any one selected from compounds represented by the following Formula 2-1, Formula 3-1, and Formula 3-2: 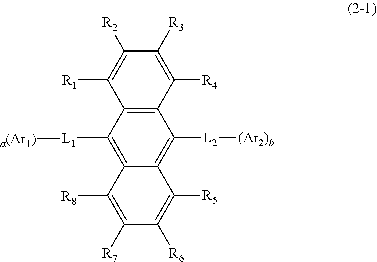
wherein,
L₁ and L₂ each independently represent a single bond, a substituted or unsubstituted (C₆-C₃₀)arylene, or a substituted or unsubstituted (3- to 30-membered)heteroarylene;
Ar₁ and Ar₂ each independently represent a substituted or unsubstituted (C₆-C₃₀)aryl or a substituted or unsubstituted (3- to 30-membered)heteroaryl;
R₁ to R₈ each independently represent hydrogen, deuterium, halogen, cyano, a substituted or unsubstituted (C₁-C₃₀)alkyl, a substituted or unsubstituted (C₂-C₃₀)alkenyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₃-C₃₀)alkenylcycloalkenyl, a substituted or unsubstituted (3- to 7-membered)heterocycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, a substituted or unsubstituted mono- or di(C₁-C₃₀)alkylamino, a substituted or unsubstituted mono- or di(C₂-C₃₀)alkenylamino, a substituted or unsubstituted mono- or di(C₆-C₃₀)arylamino, a substituted or unsubstituted mono- or di(3- to 30-membered)heteroarylamino, a substituted or unsubstituted (C₁-C₃₀)alkyl(C₂-C₃₀)alkenylamino, a substituted or unsubstituted (C₁-C₃₀)alkyl(C₆-C₃₀)arylamino, a substituted or unsubstituted (C₁-C₃₀)alkyl(3- to 30-membered)heteroarylamino, a substituted or unsubstituted (C₂-C₃₀)alkenyl(C₆-C₃₀)arylamino, a substituted or unsubstituted (C₂-C₃₀)alkenyl(3- to 30-membered)heteroarylamino, or a substituted or unsubstituted (C₆-C₃₀)aryl(3- to 30-membered)heteroarylamino; and
a and b each independently represent an integer of 1 or 2, and when a and b are 2, each of Ar₁ and Ar₂ may be the same or different; 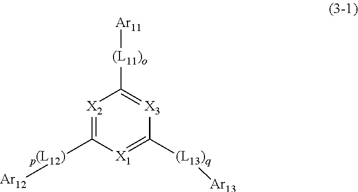
wherein,
X₁ to X₃ each independently represent CR′ or N; provided that at least two of X₁ to X₃ are N;
R′ represents hydrogen or deuterium;
L₁₁ to L₁₃ each independently represent a single bond, a substituted or unsubstituted (C₆-C₃₀)arylene, or a substituted or unsubstituted (3- to 30-membered)heteroarylene;
Ar₁₁ to Ar₁₃ each independently represent a substituted or unsubstituted (C₆-C₃₀)aryl or a substituted or unsubstituted (3- to 30-membered)heteroaryl;
o to q each independently represent 1 or 2; and
when o to q are 2 or more, each of L₁₁ to L₁₃ may be the same or different; 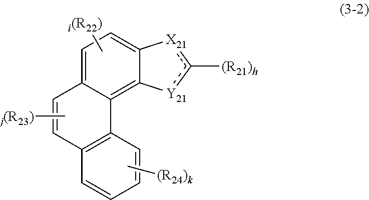
wherein,
X₂₁ represents —N═, —NR₂₇—, —O—, or —S—, and Y₂₁ represents —N═, —NR₂₈—, —O—, or —S—; provided that, when X₂₁ is —N═, Y₂₁ is —NR₂—, —O—, or —S—, and when X₂₁ is —NR₂₇—, Y₂₁ is —N═, —O—, or —S—;
provided that cases in which both X₂₁ and Y₂₁ are —O—, both are —S—, and one of X₂₁ and Y₂₁ is —O— and the other is —S— are excluded;
R₂₁ represents a substituted or unsubstituted (C₆-C₃₀)aryl or a substituted or unsubstituted (3- to 30-membered)heteroaryl;
R₂₂ to R₂₄, R₂₇, and R₂₈ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₆-C₃₀)arylamino, or a substituted or unsubstituted (C₁-C₃₀)alkyl(C₆-C₃₀)arylamino; or may be linked to an adjacent substituent to form a ring;
h is 1, i and j are each independently 1 or 2, and k is an integer of 1 to 4; and
when i and j are 2 and k is 2 or more, each of R₂₂ to R₂₄ may be the same or different.

16. The organic electroluminescent device according to claim 15, wherein, in Formula 2-1, Ar₂ is represented by the following Formula 3-11: 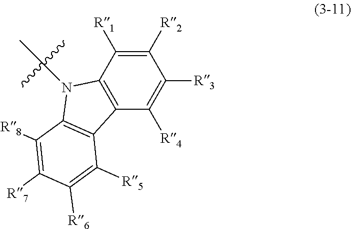
wherein,
R″₁ to R″₈ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted mono- or di(C₁-C₃₀)alkylamino, a substituted or unsubstituted mono- or di(C₆-C₃₀)arylamino, or a substituted or unsubstituted (C₁-C₃₀)alkyl(C₆-C₃₀)arylamino; or may be linked to an adjacent substituent to form a ring; and [symbol]
represents a position bonded to L₂.

17. The organic electroluminescent device according to claim 15, wherein the third light-emitting layer comprises a compound in which a difference between a first singlet energy and a second triplet energy is 0.2 eV or less.

18. The organic electroluminescent device according to claim 8, wherein the third light-emitting layer comprises a compound represented by the following Formula 3-1, as a host compound: 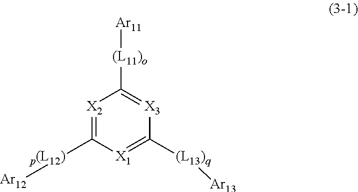
wherein,
X₁ to X₃ each independently represent CR′ or N; provided that at least two of X₁ to X₃ are N;
R′ represents hydrogen or deuterium;
L₁₁ to L₁₃ each independently represent a single bond, a substituted or unsubstituted (C₆-C₃₀)arylene, or a substituted or unsubstituted (3- to 30-membered)heteroarylene;
Ar₁₁ to Ar₁₃ each independently represent a substituted or unsubstituted (C₆-C₃₀)aryl or a substituted or unsubstituted (3- to 30-membered)heteroaryl;
o to q each independently represent 1 or 2; and
when o to q are an integer of 2, each of L₁₁ to L₁₃ may be the same or different.
